(19) United States
(12) Patent Application Publication
(10) Pub. No.: US 2018/0119268 A1
(43) Pub. Date: May 3, 2018

(54) VAPOR DEPOSITION DEVICE AND VAPOR DEPOSITION METHOD

(71) Applicant: Sharp Kabushiki Kaisha, Sakai- City, Osaka (JP)

(72) Inventors: Shinichi KAWATO, Sakai City (JP); Yuhki KOBAYASHI, Sakai City (JP); Kazuo TAKIZAWA, Sakai City (JP)

(21) Appl. No.: 15/567,616

(22) PCT Filed: Apr. 15, 2016
(86) PCT No.: PCT/JP2016/062072

§ 371 Date: Oct. 19, 2017

(30) Foreign Application Priority Data
Apr. 22, 2015 (JP) 2015-087883

(51) Int. Cl. C23C 14/04; H01L 51/56; H01L 51/00; H05B 33/10

(52) U.S. Cl. CPC C23C 14/042; H01L 51/56; H05B 33/10; H01L 51/001; H01L 51/0011

(57) ABSTRACT

A vapor deposition device (1) includes: a vapor deposition source (30); a vapor deposition mask (10) having a plurality of mask openings (12); and a limiting plate unit (20) having a plurality of limiting plates (22). The limiting plate unit is configured such that, in a cross section parallel to an X axis direction, (i) the limiting plate unit includes at least one limiting plate opening (23), each of which is formed between the limiting plates and opposite to a respective one of at least one target region (202) of a target substrate (200) such that the at least one limiting plate opening and the at least one target region are in one-to-one correspondence and (ii) the limiting plate unit prevents entry into the mask openings by vapor deposition particles (310) whose angle of entry is less than a shadow critical angle.

### TECHNICAL FIELD

The present invention relates to a vapor deposition device and a vapor deposition method each of which are for forming, on a vapor deposition target substrate having at least one vapor deposition target region, a vapor-deposited film having a predetermined pattern, the vapor-deposited film being formed in the at least one vapor deposition target region.

### BACKGROUND ART

Recent years have witnessed practical use of flat-panel displays in various products and fields. This has led to a demand for a flat-panel display that is larger in size, that achieves higher image quality, and that consumes less power.

Under such circumstances, great attention has been drawn to an EL display device that (i) includes an EL element which uses electroluminescence (hereinafter abbreviated to “EL”) of an organic or inorganic material and that (ii) is an all-solid-state flat-panel display which is excellent in, for example, low-voltage driving, high-speed response, and light-emitting characteristics.

In order to achieve a full-color display, an EL display device includes a luminescent layer which outputs light of a desired color in correspondence with a plurality of sub-pixels constituting a pixel.

A luminescent layer is formed as a vapor-deposited film on a film formation target substrate (this substrate hereinafter also referred to simply as a “target substrate”). Specifically, in a vapor deposition process, a fine metal mask (FMM) having high-precision openings is used as a vapor deposition mask, and differing vapor deposition particles are vapor deposited to each region of the target substrate.

Typically used in a mass production process is a method in which vapor deposition is carried out while a vapor deposition mask is caused to be in close contact with the target substrate, the vapor deposition mask having a size equivalent to that of the target substrate.

However, in recent years, the size of target substrates has been progressively increasing, in view of improving productivity. In a case where a large target substrate is used, it is difficult to ensure uniform close contact between the target substrate and a vapor deposition mask having a size equivalent to that of the target substrate.

In order to address this issue, there have been proposed methods in which a vapor deposition region of a large target substrate is divided into a plurality of sections, and vapor deposition is carried out while the target substrate is caused to move, with use of a vapor deposition mask smaller than the target substrate (see, for example, Patent Literature 1).

### CITATION LIST

### Patent Literature

[Patent Literature 1]

Japanese Patent Application Publication Tokukai No. 2013-55039 (Publication date: Mar. 21, 2013)

[Patent Literature 2]

Japanese Patent Application Publication Tokukai No. 2006-152441 (Publication date: Jun. 15, 2006)

### SUMMARY OF INVENTION

### Technical Problem

However, a mask opening of a vapor deposition mask is typically formed by use of etching, lasers, or the like. This causes the mask opening to have a specific cross-sectional shape. In Patent Literature 1 as well, etching is used to form slits as mask openings in a vapor deposition mask.

In a case where a vapor-deposited film pattern is formed by causing vapor deposition particles to enter such mask openings, depending on the shape and position of openings in the vapor deposition mask, the vapor-deposited film may not be formed in the correct pattern.

A problematic issue in such cases is the presence of vapor deposition particles which enter mask openings obliquely. Depending on the angle of entry, such vapor deposition particles may not be able to pass through the mask openings and reach the target substrate. This results in a problem typically known as a shadow, in which film thickness gradually decreases from the center of a mask opening toward the edges thereof. This can cause, for example, an indistinctly formed outline and a failure to form part of a pixel.

With a typical vapor deposition device, there are vapor deposition particles which enter mask openings obliquely, and, therefore, a shadow and patterning defects will occur. This places significant limitations on processes and devices.

With the techniques of Patent Literature 1, the direction of vapor deposition particles which reach the target substrate is not limited, and as a result, there are vapor deposition particles which enter mask openings at a small angle. This unfortunately causes a shadow to occur and prevents accurate patterning. In particular, with a mass production device, it is desirable to use a line source as a vapor deposition source in order to increase throughput, but doing so causes a particularly prominent shadow.

The present invention has been made in view of the above problem. An object of the present invention is to provide a vapor deposition device and a vapor deposition method, each of which prevents indistinct outlines and pixel defects caused by a shadow.

### Solution to Problem

In order to solve the above problems, a vapor deposition device in accordance with an aspect of the present invention is a vapor deposition device for forming, on a target substrate having at least one target region, a plurality of vapor-deposited films having a predetermined pattern which are spaced from each other in at least a first direction, the plurality of vapor-deposited films being formed in the at least one target region, the vapor deposition device including: a vapor deposition source having a plurality of vapor deposition source openings for emitting vapor deposition particles; a vapor deposition mask provided opposite to the at least one target region, the vapor deposition mask having a mask opening region constituted by a plurality of mask openings provided along at least the first direction in correspondence with the predetermined pattern of the plurality of vapor-deposited films, each of the plurality of mask openings having a cross-sectional shape which is tapered toward the target substrate; and a limiting plate unit provided between the vapor deposition source and the vapor deposition mask, the limiting plate unit having a plurality of limiting plates which are provided along at least the first direction so as to be spaced from each other, the limiting plate unit being configured such that, in a cross section of the limiting plate unit which cross section is parallel to the first direction, (i) the limiting plate unit includes at least one limiting plate opening, each of which is formed between a respective pair of mutually adjacent ones of the plurality of limiting plates and opposite to a respective one of the at least one target region such that the at least one limiting plate opening and the at least one target region are in one-to-one correspondence, (ii) a central axis of each of the at least one limiting plate opening is aligned with a central axis of a respective one of the at least one target region, and (iii) the following Formula (1) is satisfied:

Wr≤2/tanα×Db−Wp (1)

where Wp is a width, as measured in the first direction, of each of the at least one target region; Wr is a width of each of the at least one limiting plate opening as measured in the first direction at a face of each of the at least one limiting plate opening which face is on a side toward a surface of the limiting plate unit which surface faces the vapor deposition source; Db is a distance from (a) a target surface of the target substrate to (b) a surface of each of the limiting plates which surface faces the vapor deposition source; and a is an angle of inclination of an opening wall of each of the plurality of mask openings as observed in a cross section of the vapor deposition mask which cross section is parallel to the first direction.

In order to solve the above problems, a method of vapor deposition in accordance with an aspect of the present invention includes forming, on a target substrate having at least one target region, a plurality of vapor-deposited films having a predetermined pattern which are spaced from each other in at least a first direction, the plurality of vapor-deposited films being formed in the at least one target region, the forming being carried out with use of a vapor deposition device in accordance with an aspect of the present invention.

### Advantageous Effects of Invention

An embodiment of the present invention makes it possible to provide a vapor deposition device and a vapor deposition method, each of which prevents indistinct outlines and pixel defects caused by a shadow.

### BRIEF DESCRIPTION OF DRAWINGS

FIG. 1 is a cross-sectional view illustrating a basic configuration of a vapor deposition device in accordance with Embodiment 1 of the present invention.

FIG. 2 is a perspective view illustrating a basic configuration of the vapor deposition device in accordance with Embodiment 1 of the present invention.

FIG. 3 is a cross-sectional view schematically illustrating an example configuration of main parts of the vapor deposition device in accordance with Embodiment 1 of the present invention.

(a) and (b) of FIG. 4 are each a cross-sectional view illustrating a relationship between an angle of entry of vapor deposition particles into a mask opening and a pattern of a vapor-deposited film.

FIG. 5 is a cross-sectional view illustrating a basic configuration of a vapor deposition device in accordance with Embodiment 2 of the present invention.

FIG. 6 is a cross-sectional view illustrating a basic configuration of a vapor deposition device in accordance with Embodiment 3 of the present invention.

FIG. 7 is a cross-sectional view illustrating another configuration of a vapor deposition device in accordance with Embodiment 3 of the present invention.

FIG. 8 is a cross-sectional view illustrating a basic configuration of a vapor deposition device in accordance with Embodiment 4 of the present invention.

### DESCRIPTION OF EMBODIMENTS

The following description will discuss, in detail, embodiments of the present invention.

### Embodiment 1

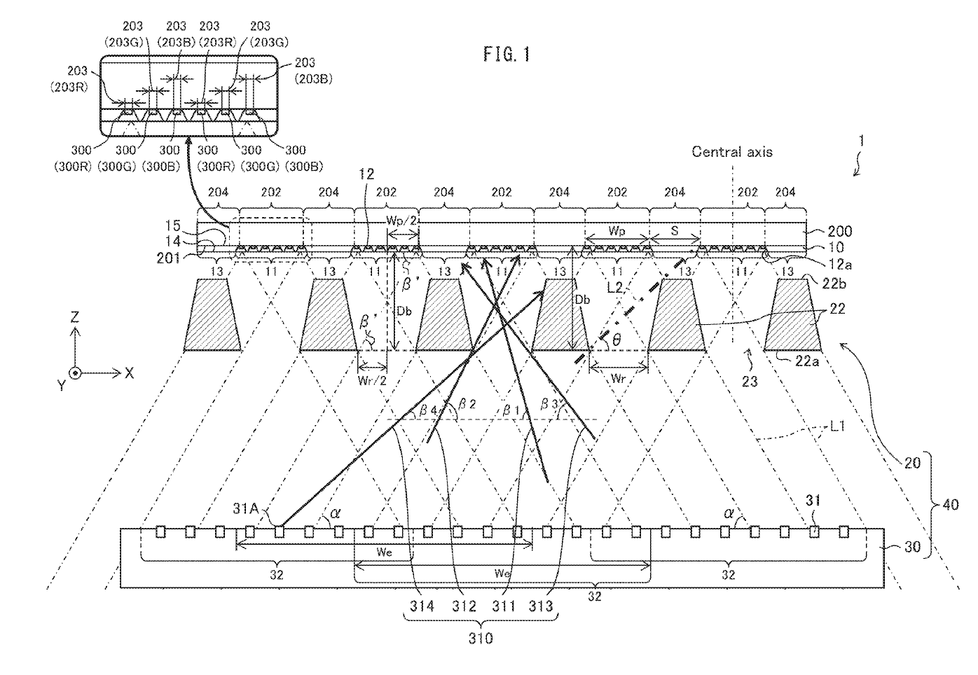

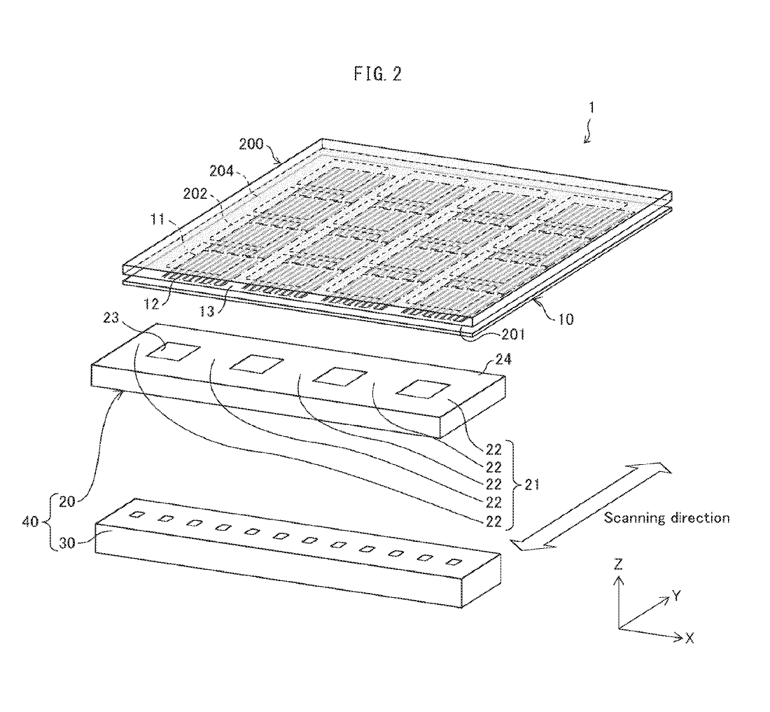

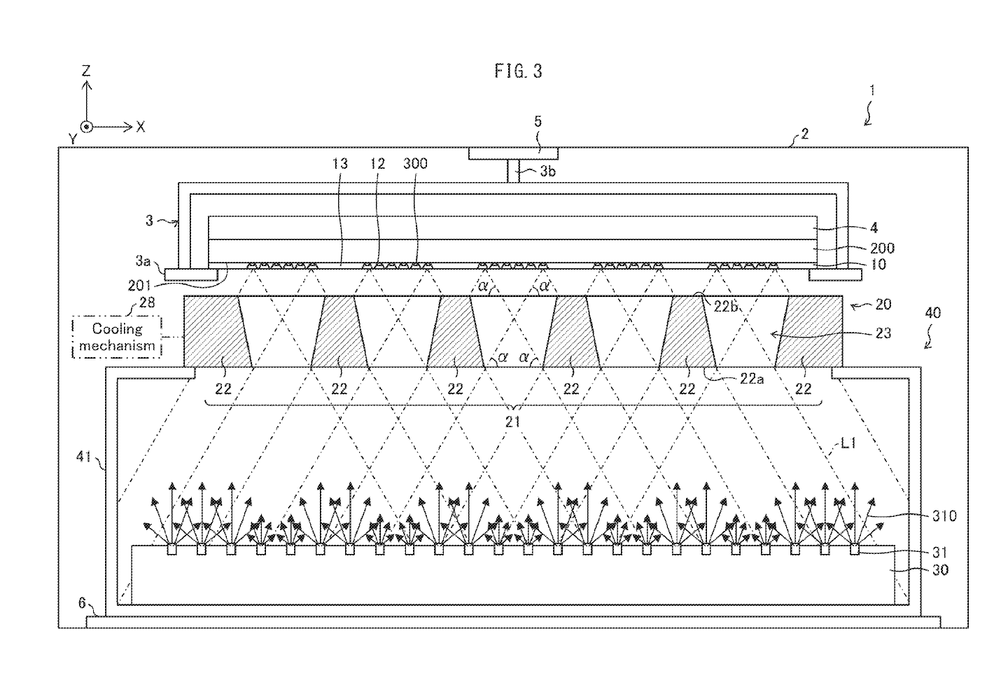

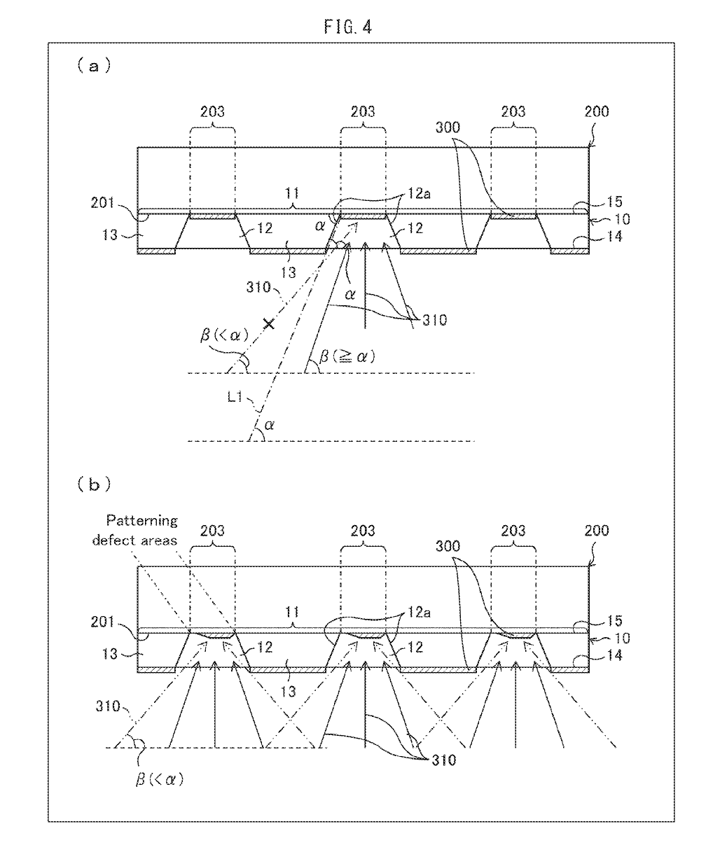

FIG. 1 is a cross-sectional view illustrating a basic configuration of a vapor deposition device 1 in accordance with Embodiment 1. FIG. 2 is a perspective view illustrating a basic configuration of the vapor deposition device 1 in accordance with Embodiment 1. FIG. 3 is a cross-sectional view schematically illustrating an example configuration of main parts of the vapor deposition device 1 in accordance with Embodiment 1.

The vapor deposition device 1 in accordance with Embodiment 1 and a vapor deposition method in accordance with Embodiment 1 are each particularly useful for vapor deposition of an EL layer such as a luminescent layer included in an EL element, the EL element being in an EL display device such as an organic EL display device.

The following description will discuss an example in which the vapor deposition device 1 and the vapor deposition method in accordance with Embodiment 1 are applied to production of an organic EL display device for RGB full-color display, in which organic EL display device organic EL elements of the colors red (R), green (G), and blue (B) have been formed as sub-pixels in an array on a substrate. The following description will exemplarily discuss a case where an RGB selective method is used for film formation of a luminescent layer of an organic EL element.

In other words, the following description will exemplarily discuss a case where vapor-deposited films 300 formed by use of the vapor deposition device 1 serve as luminescent layers of the colors R, G, and B in an organic EL display device. Note, however, that Embodiment 1 is not limited to such an example. The vapor deposition device 1 and vapor deposition method in accordance with Embodiment 1 can be applied in general to production of devices which production utilizes a vapor deposition technique, including the production of organic EL display devices and inorganic EL display devices.

In Embodiment 1, as illustrated in FIG. 1, the vapor-deposited films 300 constituting luminescent layers of the colors R, G, and B in an organic EL display device will be denoted as vapor-deposited film 300R, vapor-deposited film 300G, and vapor-deposited film 300B, respectively. However, in cases where it is not particularly necessary to distinguish between the vapor-deposited films 300R, 300G, and 300B, the vapor-deposited films 300R, 300G, and 300B are simply referred to collectively as vapor-deposited films 300.

Note that the following description assumes that (i) a Y axis is a horizontal axis extending in a scanning direction (along a scanning axis) of a target substrate 200, (ii) an X axis is a horizontal axis extending in a direction perpendicular to the scanning direction of the target substrate 200, and (iii) a Z axis is a vertical axis which is perpendicular to each of the X axis and the Y axis, which is a direction normal to a film formation target surface (hereinafter also referred to as a “target surface”) 201 of the target substrate 200. The following description assumes that an X axis direction is a “row” direction (first direction) and a Y axis direction is a “column” direction (second direction). Note also that, for convenience, the following description assumes that a side to which the upward arrow of the Z axis points in FIG. 1 is up (an upper side), unless mentioned otherwise.

<Main Configuration of Vapor Deposition Device 1>

As illustrated in FIGS. 1 and 3, the vapor deposition device 1 is a device for forming the vapor-deposited films 300 in a film formation target region 202 (vapor-deposited film patterning region; hereinafter also referred to as a “target region”) of the target surface 201 of the target substrate 200.

The vapor deposition device 1 in accordance with Embodiment 1 includes, as essential components thereof, a vapor deposition mask 10, a limiting plate unit 20, and a vapor deposition source 30.

The limiting plate unit 20 and the vapor deposition source 30 are rendered a unit by being positionally fixed with respect to each other. The limiting plate unit 20 and the vapor deposition source 30 can, for example, be fixed to each other by a rigid member. The limiting plate unit 20 and the vapor deposition source 30 can have independent respective configurations and be controlled to operate as a single unit. The limiting plate unit 20 and the vapor deposition source 30 move, as a single unit, in the scanning direction as illustrated in FIG. 2. This allows the formation of the vapor-deposited films 300 in, ultimately, all target regions 202 of the target substrate 200.

The following description will exemplarily discuss a case where the limiting plate unit 20 and the vapor deposition source 30 are rendered a unit, namely a vapor deposition unit 40, by each being held by the same holder 41 (limiting plate holding member), as illustrated in FIG. 3.

In one example, the vapor deposition device 1 of Embodiment 1 includes, for example, a film formation chamber 2, a mask holder 3, a magnet plate 4, a substrate moving device 5, the vapor deposition mask 10, the vapor deposition unit 40, a vapor deposition unit moving device 6, a deposition preventing plate (not illustrated), a shutter (not illustrated), and a control device (not illustrated).

(Film Formation Chamber 2)

In the film formation chamber 2, a vacuum pump (not illustrated) is provided for vacuum-pumping the film formation chamber 2 via an exhaust port (not illustrated) thereof to keep a vacuum in the film formation chamber 2 during vapor deposition. The vacuum pump is provided externally to the film formation chamber 2. The control device for controlling operations of the vapor deposition device 1 is also provided externally to the film formation chamber 2. Note that the mask holder 3, the magnet plate 4, the substrate moving device 5, the vapor deposition mask 10, the vapor deposition unit 40, the vapor deposition unit moving device 6, the deposition preventing plate (not illustrated), and the shutter (not illustrated) are provided within the film formation chamber 2.

(Mask Holder 3)

The mask holder 3 in accordance with Embodiment 1 serves as both a substrate holding member and a mask holding member.

As illustrated in FIG. 3, the mask holder 3 includes, for example, a mask mount 3a onto which the vapor deposition mask 10 is mounted. Mounting the vapor deposition mask 10 and the target substrate 200 onto the mask mount 3a causes the vapor deposition mask 10 and the target substrate 200 to be held in contact (close contact) with each other.

In Embodiment 1, the target substrate 200 and the vapor deposition mask 10 are subjected to alignment before vapor deposition so as to be in contact with each other or within adequate proximity to each other.

Note that in a case where the target substrate 200 and the vapor deposition mask 10 are provided in a state of non-contact with each other, the mask holder 3 need only to allow the vapor deposition mask 10 to be mounted thereto. In such a case, the vapor deposition device 1 may include a substrate holder (not illustrated) as a substrate holding member separate from the mask holder 3.

In a case where the target substrate 200 and the vapor deposition mask 10 are provided in a state of non-contact with each other, the substrate holder can be a substrate holding member which holds the target substrate 200 such that the target surface 201 of the target substrate 200 is opposite from and a certain distance away from the vapor deposition mask 10. For example, a substrate attracting device such as an electrostatic chuck can be suitably used as the substrate holder. The target substrate 200, being attracted and held by an electrostatic chuck, is fixed to the substrate holder without being bent by its own weight.

Note that a deposition preventing plate (shielding plate; not illustrated), a shutter (not illustrated), and/or the like can be provided below the mask holder 3 in order to prevent unnecessary vapor deposition particles 310 from adhering to the vapor deposition mask 10, target substrate 200, and/or the like.

(Magnet Plate 4)

In a case where (i) the target substrate 200 and the vapor deposition mask 10 are provided in a state of contact with each other and (ii) a mask having a metallic layer is used as the vapor deposition mask 10, the vapor deposition device 1 may include the magnet plate 4 as a magnetic attracting member, as illustrated in FIG. 3.

By providing the magnet plate 4 opposite the vapor deposition mask 10 so as to sandwich the target substrate 200 and magnetically attracting the metallic layer of the vapor deposition mask 10, it is possible to improve close contact between the vapor deposition mask 10 and the target substrate 200.

(Substrate Moving Device 5 and Vapor Deposition Unit Moving Device 6)

The vapor deposition device 1 in accordance with Embodiment 1 includes, for example, at least one of the substrate moving device 5 and the vapor deposition unit moving device 6. With such a configuration, Embodiment 1 is arranged to carry out scan vapor deposition by using at least one of the substrate moving device 5 and the vapor deposition unit moving device 6 to move the target substrate 200 and the vapor deposition unit 40 relative to each other such that the scanning direction corresponds to the Y axis direction.

As described above, FIG. 2 exemplarily illustrates a case where the limiting plate unit 20 and the vapor deposition source 30 are moved, as a single unit, in the scanning direction.

The substrate moving device 5 and the vapor deposition unit moving device 6 are not particularly limited and may each be any of a variety of known moving devices, such as a roller moving device or a hydraulic moving device.

The target substrate 200 and the vapor deposition unit 40 need only be provided in a manner such that at least one can move with respect to the other. As such, it is possible to employ a configuration in which only one from the group consisting of the substrate moving device 5 and the vapor deposition unit moving device 6 is provided. One from the group consisting of the target substrate 200 and the vapor deposition unit 40 may be fixed to an inner wall of the film formation chamber 2.

(Vapor Deposition Mask 10)

As illustrated in FIG. 2, the target surface 201 of the target substrate 200 is provided with a plurality of target regions 202, which are partitioned from each other as vapor-deposited film patterning regions. Each of the target regions 202 is provided in a matrix. A film-non-formation region 204 is provided so as to surround each of the target regions 202.

In the example illustrated in FIG. 2, the target substrate 200 includes eight target regions 202 which are rectangular and which are provided in four rows and four columns.

The vapor deposition mask 10 has a size such that it is large enough to cover all of the target regions 202 of the target substrate 200. The vapor deposition mask 10 therefore has a size which is, for example, identical to the size of the target substrate 200 in a planar view, as illustrated in FIG. 2. Note that the “planar view” refers to a case where the vapor deposition mask 10 is viewed from a direction orthogonal to a main surface thereof (that is, from a direction parallel to the Z axis).

The vapor deposition mask 10 may be used as is, or may be fixed, in a tensioned state, to a mask frame (not illustrated) in order to prevent the vapor deposition mask 10 from bending due to its own weight. The mask frame is formed so as to have a rectangular contour that, in a planar view, is identical to that of vapor deposition mask 10 or is somewhat larger than that of the vapor deposition mask 10.

The vapor deposition mask 10 is plate-like and has a mask surface, which is a main surface thereof and which is parallel to the XY plane, similarly to the target surface 201 of the target substrate 200. The vapor deposition mask 10 and the target substrate 200 are positionally fixed with respect to each other.

Note that it is desirable for the vapor deposition mask 10 to be provided so as to be in close contact with the target surface 201 of the target substrate 200. However, it is not necessary for the vapor deposition mask 10 to be in close contact with the target surface 201, as long as the vapor deposition mask 10 is provided so as to be within adequate proximity to the target surface 201.

In other words, the vapor deposition mask 10 is provided opposite to the target surface 201 of the target substrate 200 so as to be in contact therewith, and it is desirable for the vapor deposition mask 10 to be provided so as to be in close contact with the target surface 201. However, the vapor deposition mask 10 may be partially in contact with the target surface 201, and it is not necessary for the entirety of the vapor deposition mask 10 to be in contact with the target surface 201, as long as the vapor deposition mask 10 is provided so as to be within adequate proximity to the target surface 201.

In Embodiment 1, formed in advance in each of the target regions 202 are (i) driving circuitry (not illustrated) for an organic EL display device and (ii) one electrode (not illustrated) out of a pair of electrodes which will sandwich a luminescent layer of an organic EL element.

For convenience of explanation, Embodiment 1 exemplarily discusses a case where an organic EL element includes a luminescent layer as an organic EL layer between a pair of electrodes. Note, however, that the organic EL layer may include an organic layer other than the luminescent layer. As such, after formation of the one electrode, the vapor deposition device 1 and the vapor deposition method in accordance with Embodiment 1 may be used to form, as the vapor-deposited films 300, an organic layer other than the luminescent layer. The vapor deposition device 1 and the vapor deposition method in accordance with Embodiment 1 may also be used to form, as the vapor-deposited films 300, a luminescent layer in each of the target regions 202 of the target substrate 200 after the one electrode and the organic layer other than the luminescent layer have already been formed in each of the target regions 202.

Provided in each of the target regions 202 are sub-pixels of the colors R, G, and B, which are constituted by organic EL elements of each respective color. In each sub-pixel, the vapor-deposited films 300 are formed in a fine pattern. The pattern is constituted by the vapor-deposited films 300R, 300G, and 300B for each color, which films are used as luminescent layers of each organic EL element.

As such, each of the target regions 202 includes film formation target pattern regions (hereinafter also referred to as “target pattern regions”) 203R, 203G, and 203B in which patterns of the vapor-deposited films 300R, 300G, and 300B, respectively, are formed in correspondence with each sub-pixel, as illustrated in FIG. 1. The vapor-deposited film 300R for the color red is formed in the target pattern region 203R. The vapor-deposited film 300G for the color green is formed in the target pattern region 203G. The vapor-deposited film 300B for the color blue is formed in the target pattern region 203B. Note that in the following descriptions, in cases where it is not particularly necessary to distinguish between the target pattern regions 203R, 203G, and 203B, the target pattern regions 203R, 203G, and 203B are simply referred to collectively as target pattern regions 203.

The main surface of the vapor deposition mask 10 includes a plurality of mask opening regions 11. Each of the mask opening regions 11 includes a group of mask openings 12 in correspondence with the respective patterns of the vapor-deposited films 300R, 300G, and 300B, as illustrated in FIGS. 1 and 2.

In other words, as illustrated in FIG. 2, the vapor deposition mask 10 includes the plurality of mask opening regions 11, each of which is positioned opposite one of the target regions 202 of the target substrate 200 when the vapor deposition mask 10 is positioned opposite the target substrate 200. Each of the mask opening regions 11 has a plurality of openings (through holes) which are provided as the mask openings 12. The plurality of openings function as passages through which the vapor deposition particles 310 (vapor deposition material) pass during vapor deposition. Regions of the vapor deposition mask 10 other than the mask openings 12 are non-opening regions 13 which serve as blocking sections that block the flow of vapor deposition particles 310 during vapor deposition.

Each of the mask openings 12 is arranged so as to correspond to a pattern of the vapor-deposited films 300 which are is formed by use of the vapor deposition mask 10. Furthermore, each of the mask openings 12 is arranged so that vapor deposition particles 310 do not adhere to regions of the target substrate 200 other than desired ones of the target pattern regions 203 (that is, other than ones of the target pattern regions 203 for the color of the film to be formed by use of the vapor deposition mask 10).

As described above, luminescent layers of an organic EL display device that are made of the vapor deposition material are vapor-deposited for each color of the luminescent layers during an organic EL vapor deposition process.

A vapor deposition mask 10 for forming a red luminescent layer is used to form the vapor-deposited film 300R, which is a luminescent layer of the color red. A vapor deposition mask 10 for forming a green luminescent layer is used to form the vapor-deposited film 300G, which is a luminescent layer of the color green. Similarly, a vapor deposition mask 10 for forming a blue luminescent layer is used to form the vapor-deposited film 300B, which is a luminescent layer of the color blue.

Only the vapor deposition particles 310 that have passed through the mask openings 12 reach the target substrate 200, so that a vapor-deposited film 300 having a pattern corresponding to each of the mask openings 12 is formed on the target substrate 200.

In the example illustrated in FIG. 2, each of the mask opening regions 11 has a plurality of mask openings 12 which have a long and narrow slit-like shape. The plurality of mask openings 12 extend in the column direction and are spaced from each other in the row direction. However, the mask openings 12 can be, for example, slot-like. The shape of the mask openings 12 and the mask opening regions 11 as seen in a planar view, and the number of the mask openings 12 and the mask opening regions 11 are not limited to the exemplary shapes and numbers illustrated in FIG. 2. A cross-sectional shape of the mask openings 12 will be discussed later.

In Embodiment 1, a fine metal mask (FMM) is used as the vapor deposition mask 10. The vapor deposition mask 10 is typically made from, for example, invar (an iron-nickel alloy) which has a low thermal expansion coefficient. The vapor deposition mask 10 has a thickness which is typically in a range from several tens to several hundreds of pmm. Invar can be used suitably because it exhibits little heat-induced deformation.

A material from which the vapor deposition mask 10 is made is not limited to metals such as invar. The material from which the vapor deposition mask 10 is made can be (i) organic matter (resin) such as polyimide, (ii) an oxide such as Al₂O₃, (iii) ceramic, or (iv) a combination of any of these.

(Vapor Deposition Unit 40)

As discussed above, the vapor deposition unit 40 is configured so as to be a unit which includes the limiting plate unit 20 and the vapor deposition source 30. In Embodiment 1, the limiting plate unit 20 and the vapor deposition source 30 are rendered a unit by each being held by the same holder 41, as illustrated in FIG. 3. As such, the vapor deposition unit 40 in accordance with Embodiment 1 includes the limiting plate unit 20, the vapor deposition source 30, and the holder 41.

The holder 41 holds the limiting plate unit 20 and the vapor deposition source 30 such that the limiting plate unit 20 and the vapor deposition source 30 are positionally fixed with respect to each other.

The vapor deposition unit 40 is provided so as to be directly below the vapor deposition mask 10 and spaced from the vapor deposition mask 10. The following description will discuss the limiting plate unit 20 and the vapor deposition source 30 in more detail.

(Vapor Deposition Source 30)

The vapor deposition source 30 is a container containing, for example, a vapor deposition material. The vapor deposition source 30 may be a container directly containing a vapor deposition material, or may alternatively include a load-lock pipe so that a vapor deposition material is supplied to the vapor deposition source 30 from an external source.

As illustrated in FIG. 2, the vapor deposition source 30 has, for example, a rectangular shape. The vapor deposition source 30 has a top surface (that is, a surface facing the limiting plate unit 20) having a plurality of vapor deposition source openings 31 (through holes, nozzles) which serve as emission holes from which vapor deposition particles 310 are emitted. The vapor deposition source openings 31 are arranged in a line in the X axis direction, at a predetermined pitch.

The vapor deposition source 30 generates vapor deposition particles 310 in the form of a gas by heating a vapor deposition material so that the vapor deposition material is evaporated (in a case where the vapor deposition material is a liquid material) or sublimated (in a case where the vapor deposition material is a solid material). The vapor deposition source 30 emits, from the vapor deposition source openings 31 and toward the limiting plate unit 20, the gaseous vapor deposition material as vapor deposition particles 310.

In this way, in Embodiment 1, it is possible to use a line-type vapor deposition source having a plurality of vapor deposition source openings 31 as the vapor deposition source 30. Furthermore, by causing the vapor deposition source 30 to move in the Y axis direction, it is possible to achieve uniform film formation on the target substrate 200, which has a large surface area. This is greatly advantageous, as it prevents the occurrence of a reduction of throughput during mass production.

(Limiting Plate Unit 20)

The limiting plate unit 20 is provided so as to be (i) between the vapor deposition mask 10 and the vapor deposition source 30 and (ii) spaced from the vapor deposition mask 10 and the vapor deposition source 30.

The limiting plate unit 20 includes a limiting plate row 21 which is constituted by a plurality of limiting plates 22. The limiting plates 22 are provided such that, in a planar view, the limiting plates 22 are parallel to each other and spaced from each other in the X axis direction. As such, limiting plate openings 23 are formed as openings between ones of the limiting plates 22 which ones are mutually adjacent in the X axis direction.

Note that in Embodiment 1, as illustrated in FIG. 2, the limiting plate unit 20 is a block-like unit. Specifically, the limiting plate unit 20 is a single block which has a main surface in the XY plane and a rectangular shape whose long axis is the X axis direction. The single block has the plurality of limiting plate openings 23 (openings), which are provided in the X axis direction at a predetermined pitch. With this configuration, the limiting plate unit 20 as illustrated in FIG. 2 is configured such that a plurality of limiting plates 22 are arranged in the X axis direction at a predetermined pitch such that each of the limiting plates 22 is between mutually adjacent ones of the limiting plate openings 23.

In the single block constituting the limiting plate unit 20 as illustrated in FIG. 2, the plurality of limiting plates 22 and holding sections 24 which hold and connect the limiting plates 22 are integrally formed by portions other than the limiting plate openings 23 (that is, by portions which are non-opening regions).

Note, however, that the limiting plate unit 20 in accordance with Embodiment 1 is not limited to the configuration illustrated in FIG. 2. The limiting plate unit 20 can be configured such that the limiting plates 22, which are arranged so as to have limiting plate openings 23 therebetween, are fixed by screws, welding, or the like to holding sections which hold and connect the limiting plates 22.

In other words, each of the limiting plates 22 may be formed integrally with each other and integrally with the holding sections 24 as illustrated in FIG. 2, or the limiting plates 22 may be separately from each other and separately from the holding sections 24.

The method for holding the limiting plates 22 is not limited to the above method, and may be any method that allows relative positions and orientations of the limiting plates 22 to be fixed.

The limiting plate unit 20 may have any shape that satisfies the conditions described later. However, the limiting plate unit 20 preferably has a block-like shape as illustrated in FIG. 2. Forming the limiting plate unit 20 so as to have a block-like shape makes it possible for the limiting plate unit 20 to be compact in size. Forming the limiting plate unit 20 so as to have a block-like shape is also advantageous in that, for example, doing so makes it easy to align each of the limiting plates 22 and easy to replace the limiting plate unit 20.

The limiting plate openings 23 and the target regions 202 are provided so as to have a one-to-one relationship.

In Embodiment 1, in a planar view, each of the limiting plate unit 20 and the vapor deposition source 30 has a size (width), as measured in the Y axis direction, which is smaller than that of each of the vapor deposition mask 10 and the target substrate 200. Vapor deposition is carried out while moving (i) the vapor deposition mask 10 and the target substrate 200 as a unit and (ii) the limiting plate unit 20 and the vapor deposition source 30 (specifically, the vapor deposition unit 40) as a unit with respect to each other, so as to vapor deposit one column at a time in the Y axis direction. This forms the patterns of the vapor-deposited films 300 in each of the target regions 202 of the target substrate 200.

The limiting plate unit 20 therefore has one row (put otherwise, one column in the X axis direction) of limiting plate openings 23 which correspond to the target regions 202 of the target substrate 200.

The limiting plate openings 23 are arranged at a pitch larger than that of the mask openings 12 such that, in a planar view, a plurality of mask openings 12 are positioned between two limiting plates 22 adjacent to each other in the X axis direction.

Furthermore the limiting plate openings 23 are arranged at a pitch larger than that of the vapor deposition source openings 31 such that, in a planar view, a plurality of limiting plate openings 23 are positioned between two limiting plates 22 adjacent to each other in the X axis direction. In other words, there are at least two vapor deposition source openings 31 corresponding to each one of the limiting plate openings 23 of the limiting plate unit 20. As such, the vapor deposition source openings 31 and the limiting plate openings 23 do not have a one-to-one relationship. Therefore, with Embodiment 1, it is possible to greatly increase a vapor deposition rate in comparison to a configuration where the vapor deposition source openings 31 and the limiting plate openings 23 have a one-to-one relationship. This brings about device-related advantages in that (i) it makes it possible to enhance mass production efficiency and (ii) it makes it easy to design a vapor deposition source.

Vapor deposition particles 310 emitted from the vapor deposition source openings 31 initially spread in a substantially isotropic manner, as illustrated in FIG. 3. Note that in FIG. 3, arrows provide a simplified indication of the flow of vapor deposition particles 310 from each of the vapor deposition source openings 31. The length of each arrow corresponds to the number of vapor deposition particles. As such, for each of the limiting plate openings 23, it is vapor deposition particles 310 emitted from a vapor deposition source opening 31 positioned directly therebeneath which travel toward the limiting plate opening 23 in the greatest number. However, in addition, vapor deposition particles 310 emitted from a vapor deposition source opening 31 positioned obliquely beneath a limiting plate opening 23 will also travel toward that limiting plate opening 23.

Vapor deposition particles 310 emitted from the vapor deposition source openings 31 pass through the limiting plate openings 23 and therefore reach the vapor deposition mask 10 while being limited as to their angle of entry β into the mask openings 12. Vapor deposition particles 310 that pass through the mask openings 12 adhere to the target substrate 200, thereby forming, on the target substrate 200, a film formation pattern constituted by the vapor-deposited films 300.

The limiting plate unit 20 partitions a space between the vapor deposition mask 10 and the vapor deposition source 30 into a plurality of vapor deposition spaces, that is, the limiting plate openings 23, with use of each of the limiting plates 22. As described above, the limiting plate unit 20 has one limiting plate opening 23 for each one of the mask opening regions 11.

The limiting plate unit 20 limits the angle of entry β of the vapor deposition particles 310 into the mask openings 12 in each of the mask opening regions 11 such that the angle of entry β is not less than a shadow critical angle a. The shadow critical angle α is a critical angle α at which a shadow does not occur. Note that dotted and dashed lines L1 in FIG. 1, FIG. 3, and (a) and (b) of FIG. 4 indicate the shadow critical angle α for each of the target regions 202.

<Shadow Critical Angle>

The following description will discuss the shadow critical angle with reference to FIG. 1 and (a) and (b) of FIG. 4.

(a) and (b) of FIG. 4 are each a cross-sectional view illustrating a relationship between the angle of entry β of vapor deposition particles 310 into the mask openings 12 and a pattern of the vapor-deposited films 300. (a) of FIG. 4 illustrates a case where the angle of entry β of vapor deposition particles 310 into the mask openings 12 is not less than the shadow critical angle α (β≥α). (b) of FIG. 4 illustrates a case where there are vapor deposition particles 310 whose angle of entry β into the mask openings 12 is less than the shadow critical angle α (β<α).

A mask opening of a vapor deposition mask is typically formed by use of etching, lasers, or the like. In Embodiment 1 as well, the mask openings 12 of the vapor deposition mask 10 are formed by use of etching, such as wet etching, lasers, or the like.

As such, the mask openings 12 of the vapor deposition mask 10 have a tapered cross-sectional shape, as illustrated in FIG. 1 and (a) and (b) of FIG. 4.

The vapor deposition mask 10 is provided such that the cross-sectional shape of the mask openings 12 is tapered toward a side away from a surface 14 which faces the limiting plate unit 20, as illustrated in FIG. 1 and (a) and (b) of FIG. 4. In other words, the vapor deposition mask 10 is provided such that a pair of opposing opening walls 12a (inner walls) of each mask opening 12 are angled so that an area of each mask opening 12 decreases as proximity to a surface 15 increases, the surface 15 being a surface of the vapor deposition mask 10 which faces the target substrate 200.

This is equivalent to the vapor deposition mask 10 being provided such that opening walls 12a of each non-opening region 13 in each mask opening region 11 of the vapor deposition mask 10 have an inverse taper so as to be tapered toward the surface 14 which faces the limiting plate unit 20. Here, having an inverse taper means that, in a cross section of the vapor deposition mask 10, an angle of inclination formed by (i) the surface 14 and (ii) an opening wall 12a of each non-opening region 13 in each mask opening region 11 is greater than 90°.

A shadow is dependent on the shape of the mask openings 12. As illustrated in (a) of FIG. 4, in a case where the mask openings 12 are tapered toward the target substrate 200, the shadow critical angle α is, in a cross section of the vapor deposition mask 10 which cross section extends parallel to the

X axis direction, an angle formed by (i) an opening wall 12a of a mask opening 12 and (ii) a face of the mask openings 12 which face is on a side toward the surface 14. In other words, the angle of inclination of each of the opening walls 12a of the mask openings 12 in the cross section is the shadow critical angle α.

In a case where the mask openings 12 are tapered toward the target substrate 200, as illustrated in (b) of FIG. 4, out of vapor deposition particles 310 emitted obliquely toward the mask openings 12, those vapor deposition particles 310 having an angle of entry β into the mask openings 12 which is smaller than the shadow critical angle α cannot pass through the mask openings 12 and thus cannot reach the target substrate 200. Such vapor deposition particles 310 cause what is known as a shadow, in which film thickness gradually decreases from the center of a mask opening 12 toward the edges thereof, as illustrated in (b) of FIG. 4. This can cause, for example, an indistinctly formed outline and a failure to form part of a pixel.

<Limitation of Angle of Entry of Vapor Deposition Particles 310 into Mask Openings 12 by Limiting Plate Unit 20>

In Embodiment 1, vapor deposition particles 310 which enter the limiting plate openings 23 are selectively blocked (caught) according to the angle of entry β thereof, in order to prevent entry into the mask openings 12 by vapor deposition particles 310 whose angle of entry β into the limiting plate openings 23 is less than the shadow critical angle α, as illustrated in FIG. 1 and (a) of FIG. 4. This makes it possible to achieve accurate vapor deposition patterning without a shadow.

In other words, in a case where vapor deposition particles 310 enter the mask openings 12 only at angles not less than the shadow critical angle α, a shadow will not occur, and thus the above-described patterning defects will not occur.

As such, in Embodiment 1, the limiting plates 22 are provided such that the angle of entry β of vapor deposition particles 310 into the mask openings 12 of each mask opening region 11 are controlled to be not less than the angle of inclination of the opening walls 12a of the mask openings 12.

Therefore, in Embodiment 1, the limiting plates 22 are provided such that (i) a central axis of each of the limiting plate openings 23 is aligned with a central axis of a respective one of the target regions 202 and (ii) the following Formula (1) is satisfied:

Wr≤2/tanα×Db−Wp (1)

where Wp is a width, as measured in the X axis direction, of each of the target regions 202; Wr is a width of each of the limiting plate openings 23 as measured in the X axis direction at a face of each of the limiting plate openings 23 which face is on a side toward a surface 22a of the limiting plate unit 20 which surface 22a faces the vapor deposition source 30; and Db is a distance from (a) the target surface 201 of the target substrate 200 to (b) a surface 22a of each of the limiting plates 22 which surface 22a faces the vapor deposition source 30.

In other words, as described above, it is necessary for the angle of entry β at which vapor deposition particles 310 enter each of the target regions 202 to be not less than the shadow critical angle α (i.e., not less than the angle of inclination of opening walls 12a of the mask openings 12 as observed in a cross section of the vapor deposition mask 10 which cross section extends parallel to the X axis direction).

Thus, in the above cross section, in a case where the angle of entry β at which the vapor deposition particles 310 enter each of the target regions 202 is a minimum, vapor deposition particles 310 will enter the limiting plate openings 23 in a manner so as to graze a lower end of a respective limiting plate 22 before reaching an opposing one of the target regions 202 (that is, the vapor deposition particles 310 will reach the target regions 202 by travelling along the dotted and dashed lines L1 of FIG. 1).

As such, the angle of entry β of vapor deposition particles 310 (incident particles) which travel along the dotted and dashed lines L1 in FIG. 1 and reach the target regions 202 must be not less than α.

As such, in a case where the angle of entry β of vapor deposition particles 310 (incident particles) which travel along the dotted and dashed lines L1 and reach the target regions 202 as illustrated in FIG. 1 is represented as β′, the following formula stands:

Wr/2×tanβ′+Wp/2×tanβ′=Db

Solving this formula provides the following:

tanβ′=2×Db/(Wr+Wp)

Since β′ is greater than or equal to α, tanβ′ is greater than or equal to tanα.

As such, the following formula stands:

2×Db/(Wr+Wp)≥tanα

Solving this formula provides the Formula (1) above.

Note that in Embodiment 1, the following dimensions are not particularly limited provided that they are set so as to satisfy the conditions described above: the height of each of the limiting plates 22 (thickness along the Z axis, i.e., length of limiting plate openings 23 as measured in the Z axis direction); the width of each of the limiting plates 22 (thickness as measured in the X axis direction); the width of each of the limiting plate openings 23 as measured in the X axis direction at the surface 22a of the limiting plate unit 20 which surface 22a faces the vapor deposition source 30; the width of each of the limiting plate openings 23 as measured in the X axis direction at a surface 22b of the limiting plate unit 20 which surface 22b faces the vapor deposition mask 10; and the like.

Thus, with Embodiment 1, the limiting plate unit 20 has the limiting plate openings 23 each of which (i) is opposite to a respective one of the target regions 202 so as to form a pair with the respective one of the target regions 202 and (ii) has a central axis that is aligned with a central axis of the respective one of the target regions 202. Furthermore, the limiting plate unit 20 is designed/provided so as to satisfy Formula (1). As such, it is possible to prevent vapor deposition particles 310 whose angle of entry β into the limiting plate openings 23 is less than the shadow critical angle α from entering the mask openings 12.

Furthermore, in order to prevent vapor deposition particles 310 which, as with vapor deposition particles 314 (described in later examples), have been emitted from vapor deposition source openings 31 corresponding to (i) a respective one of the target regions 202 and (ii) a respective one of the limiting plate openings 23 from passing through the respective one of the limiting plate openings 23 and entering a target region 202 which is adjacent to the respective one of the target regions 202 (such an adjacent target region 202 hereinafter referred to as an “adjacent target region 202”), the limiting plates 22 can be provided so as to satisfy the following Formula (2):

(Db/tanθ)<(Wr+Wp)/2+S (2)

where S is a width, as measured in the X axis direction, of a film-non-formation region 204 between mutually adjacent ones of the target regions 202; and θ is an angle of inclination of a line L2 (bold dotted and dashed line in FIGS. 1, 6, and 7) which line L2 connects, in each of the limiting plate openings 23, (i) a lower end (opening wall lower end) of a first limiting plate 22 of an mutually opposed pair of the limiting plates 22 (opening walls 12a) and (ii) an upper end (opening wall upper end) of a second limiting plate 22 of the mutually opposed pair of the limiting plates 22, the mutually opposed pair of the limiting plates 22 being opposed in the X axis direction. In other words, θ is an angle of inclination formed by the line L2 and a horizontal plane.

In other words, vapor deposition particles which reach a position closest to an adjacent target region 202 of the target substrate 200 are vapor deposition particles 310 which pass through one of the limiting plate openings 23 in a manner so as to (i) pass by an lower end of a specific one of the limiting plates 22 and (ii) graze an upper end of one of the limiting plates 22 which one is opposite to the specific one of the limiting plates 22 with respect to the limiting plate opening 23, as indicated by the line L2.

As such, in a planar view, in a case where a lower end of one of the limiting plates 22 is used as a reference position, the position at which a vapor deposition particle 310 reaches target substrate 200 is a position at which the vapor deposition particle 310 has neared the adjacent target region 202 by a distance of (Db/tanθ) from the lower end of the one of the limiting plates 22.

Similarly, in a planar view, in a case where a lower end of one of the limiting plates 22 is used as a reference position, a position of an edge of an adjacent target region 202 can be expressed as Wr/2+Wp/2+S.

As such, when Formula (2) is satisfied, the left side of Formula (2) is shorter than the right side of Formula (2). The left side of Formula (2) is, in the planar view in a case where a lower end of one of the limiting plates 22 is used as a reference position, a distance from (i) the reference position to (ii) a position of a vapor deposition particle which reaches a position closest to the adjacent target region 202 of the target substrate 200. The right side of Formula (2) is a distance from (iii) the reference position to (iv) a position at an end of the adjacent target region 202.

Note that Formula (2) is not an essential condition from the viewpoint of preventing vapor deposition particles 310 whose angle of entry β is less than the shadow critical angle α from entering the mask openings 12. A path of entry into the adjacent target region 202 occurs at a low angle which is less than the shadow critical angle α.

The following description will discuss effects of the vapor deposition device 1 in accordance with Embodiment 1 by discussing, as examples of the vapor deposition particles 310, vapor deposition particles 311 to 314 which have differing angles of entry β into the limiting plate openings 23 as illustrated in FIG. 1. These differing angles of entry β are indicated as β1 through β4.

For example, in the case of the vapor deposition particles 311, the angle of entry β1 into the limiting plate openings 23 is not less than the shadow critical angle α. The vapor deposition particles 311 therefore reach a position within the target regions 202 without any problems.

In the case of the vapor deposition particles 312, while the vapor deposition particles 312 do pass through the vicinity of a corner part of one of the limiting plates 22 which corner part is on a side toward the surface 22a facing the vapor deposition source 30, the vapor deposition particles 312 successfully reach a position within the target regions 202 because the angle of entry β2 into the limiting plate openings 23 is not less than the shadow critical angle α.

In the case of the vapor deposition particles 313, the angle of entry β3 into the limiting plate openings 23 is smaller than the shadow critical angle α. The vapor deposition particles 313 pass through the limiting plate openings 23 but reach an area outside of the target regions 202. As such, the vapor deposition particles 313 do not enter the mask openings 12 and therefore do not require consideration as a factor causing a shadow in the target regions 202.

In the case of the vapor deposition particles 314, the angle of entry β3 into the limiting plate openings 23 is smaller than the shadow critical angle α. If a path of entry (direction of entry) of the vapor deposition particles 314 were extended further, the path would reach a target region 202 which is adjacent to a target region 202 entered by particles whose angle is not less than the shadow critical angle α. The vapor deposition particles 314 would therefore become a factor causing a shadow. However, in Embodiment 1, the limiting plates 22 block the vapor deposition particles 314 as illustrated in FIG. 1. This prevents vapor deposition particles 310 such as the vapor deposition particles 314, which would otherwise be a factor causing a shadow, from reaching the target regions 202.

Note that the example illustrated in FIG. 1 is configured so that vapor deposition particles 310 emitted from a single one of the vapor deposition source openings 31 will enter the following target regions 202: (i) out of pairs of the target regions 202 which are, in a planar view, separated from each other so as to sandwich the single one of the vapor deposition source openings 31 (i.e., target regions 202 other than a target region 202 which is directly above the single one of the vapor deposition source openings 31), whichever one of the pairs is closest to the single one of the vapor deposition source openings 31; and (ii) a target region 202 positioned directly above the single one of the vapor deposition source openings 31, in a case where such a target regions 202 exists.

As such, for example, vapor deposition particles 310 emitted from a vapor deposition source opening 31A, which also emits vapor deposition particles 314, will enter (i) a first target region 202 which is directly above the vapor deposition source opening 31A and (ii) second and third target regions 202 which are adjacent to the first target region 202 on either side thereof. However, as is shown with the vapor deposition particles 314, vapor deposition particles 310 will not reach other ones of the target regions 202 which are adjacent to the second and third target regions 202 so as to sandwich the second and third target regions 202.

Note, however, that the configuration discussed above is an example. The target regions 202 which are entered by vapor deposition particles 310 emitted from a single one of the vapor deposition source openings 31 can be set/altered as necessary by altering, for example, each parameter of Formulas (1) and (2), the shape of the limiting plates 22, and the distance between the limiting plate unit 20 and the vapor deposition source 30, provided that Formulas (1) and (2) are satisfied. In other words, the correspondence between (i) the target regions 202 and (ii) the limiting plate openings 23 and the vapor deposition source openings 31 can be set/altered as necessary.

<Effects>

As described above, with Embodiment 1, all vapor deposition particles 310 whose angle of entry β into the limiting plate openings 23 is less than the shadow critical angle α are blocked, by the limiting plates 22, from entering the target regions 202. As such, the limiting plate unit 20 limits the vapor deposition particles 310 such that all vapor deposition particles 310 which reach the mask openings 12 are vapor deposition particles 310 whose angle of entry is not less than the shadow critical angle α. This makes it possible to achieve accurate vapor deposition patterning without a shadow.

The present technology is particularly efficacious for high-definition patterning over a large surface area. As such, the present technology is particularly efficacious for vapor deposition carried out on a large target substrate divided into a plurality of vapor deposition regions, an example thereof being the target surface 201 provided with the plurality of target regions 202.

As illustrated in FIG. 2, the vapor deposition source 30 and the limiting plate unit 20 are rendered a unit by being positionally fixed with respect to each other, and a film is formed in all vapor deposition regions of the target substrate 200 (that is, in all target regions 202) by moving the unit back and forth. This configuration makes it possible, even for the target substrate 200 having a large surface area, to achieve high-precision patterning without a shadow occurring. This configuration also makes it possible to achieve high-definition patterning over a large surface area even when using the vapor deposition source 30 and the limiting plate unit 20 which are both relatively small. As such, the configuration enables enhanced mass production efficiency.

Furthermore, conventionally, achieving a uniform distribution of film thickness has required, for example, significant configurational adjustments to mask openings and/or providing a plurality of stages of limiting plates.

However, with Embodiment 1, it is possible to achieve a uniform distribution of film thickness simply by, for example, controlling a vapor deposition rate of vapor deposition particles 310 emitted from the vapor deposition source 30, as indicated by the arrows in FIG. 3. As such, the vapor deposition device 1 can be easily designed. The vapor deposition rate of vapor deposition particles 310 emitted from the vapor deposition source 30 will be discussed in Embodiment 2.

<Variations>

(Cooling Mechanism 28)

The limiting plates 22 desirably have a temperature which is lower than a temperature at which vapor deposition particles are generated, i.e., lower than a temperature at which the vapor deposition material becomes a gas. As such, it is preferable to cool the limiting plates 22. A cooling mechanism 28 which cools the limiting plates 22 may therefore be provided to the limiting plate unit 20, as indicated by a chain double-dashed line in FIG. 3. This makes it possible to (i) solidify and catch vapor deposition particles 310 which have collided into the limiting plates 22, (ii) prevent collisions between and scattering of vapor deposition particles 310, and (iii) prevent the limiting plates 22 from causing revaporization. This configuration therefore makes it possible to reliably limit vapor deposition flow from the vapor deposition source 30.

Furthermore, cooling the limiting plates 22 inhibits radiant heat given off by the vapor deposition source 30, thereby making it possible to prevent a rise in temperature of the target substrate 200 and of the vapor deposition mask 10. Cooling the limiting plates 22 therefore makes it possible to prevent thermal expansion of the target substrate 200 and of the vapor deposition mask 10. This makes it possible to maintain high precision. Furthermore, the above effects make it possible to bring the vapor deposition source 30 and the target substrate 200 relatively closer to each other. This enables an improved rate of film formation.

(Cross-Sectional Shape of Limiting Plate Openings 23)

FIGS. 1 and 3 exemplarily illustrate a case where the limiting plates 22 have a cross-sectional shape which is tapered toward the target substrate 200 such that (i) an area of the surface 22a of each of the limiting plates 22, which surface 22a faces the vapor deposition mask 10, is greater than (ii) an area of the surface 22b of each of the limiting plates 22, which surface 22b faces the vapor deposition mask 10. This gives the limiting plate openings 23 a cross-sectional shape which is tapered toward the vapor deposition source 30. However, the limiting plates 22 are not limited to having such a shape, provided that the above-described conditions are satisfied. As such, the cross-sectional shape of the limiting plates 22 and the shape of the limiting plate openings 23 can be rectangular, or a combination of other shapes can be used. Note that in a case where (i) the limiting plates 22 have a cross-sectional shape which is tapered toward the vapor deposition source 30 and (ii) this gives the limiting plate openings 23 a cross-sectional shape which is tapered toward the target substrate 200, Formula (1) will not be satisfied.

(Arrangement of Vapor Deposition Source 30 and Limiting Plate Unit 20)

Exemplarily discussed in Embodiment 1 was a case where scanning vapor deposition is carried out by, for example, causing the vapor deposition unit 40 to move in the Y axis direction, as illustrated in FIG. 2. However, Embodiment 1 is not limited to such a configuration. It is possible to employ a configuration in which, out of the vapor deposition source 30 and the limiting plate unit 20, at least the limiting plate unit 20 is provided so as to be opposite to the entirety of the target substrate 200 and the entirety of the vapor deposition mask 10 in a planar view. In such a case as well, it is possible to achieve high-precision patterning without a shadow occurring, even if the target substrate 200 has a large surface area.

(Target Regions 202)

Exemplarily discussed in Embodiment 1 was a case where the target substrate 200 has a plurality of target regions 202. However, the target substrate 200 need only have at least one target region 202.

As such, the vapor deposition mask 10 need only have at least one mask opening region 11 in correspondence with the at least one target region 202, and the limiting plate unit 20 need only have at least one limiting plate opening 23.

(Uses)

As described above, the present technology is particularly useful for vapor deposition of, for example, an EL layer of an organic EL display device. However, the present technology is not limited to this. The present technology can be applied to film formation technologies in general, such as production of various devices which production utilizes vapor deposition, an example being production of EL display devices such as organic EL display devices or inorganic EL display devices.

### Embodiment 2

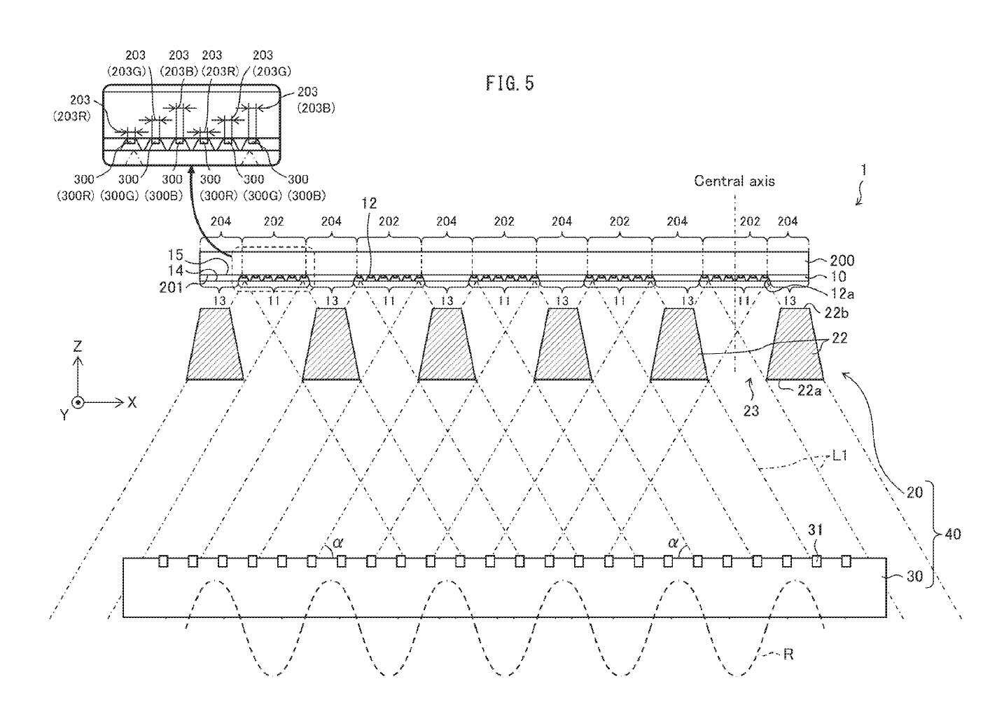

The following description will discuss another embodiment of the present invention, primarily with reference to FIG. 5. The description below will deal mainly with how the present embodiment differs from Embodiment 1. Any member of the present embodiment that is identical in function to a corresponding member of Embodiment 1 is assigned a common reference numeral, and is not described here.

<Vapor Deposition Device 1>

Discussed in Embodiment 2 is a vapor deposition rate (film formation rate; film formation speed) of vapor deposition particles 310 emitted from a vapor deposition source 30.

FIG. 5 is a cross-sectional view illustrating a basic configuration of a vapor deposition device 1 in accordance with Embodiment 2.

As illustrated in FIG. 5, the vapor deposition device 1 of Embodiment 2 is configurationally identical to the vapor deposition device 1 of Embodiment 1. As described in Embodiment 1, with the vapor deposition device 1, it is possible to achieve a uniform distribution of film thickness simply by, for example, controlling the vapor deposition rate of vapor deposition particles 310 emitted from the vapor deposition source 30.

As such, in Embodiment 2, the vapor deposition rate of vapor deposition particles 310 emitted from the vapor deposition source 30 has a distribution.

The amount of flying vapor deposition particles 310 which are emitted from each of the vapor deposition source openings 31 has a distribution. For example, as indicated by arrows in FIG. 3, generally, the maximum value is that for vapor deposition particles 310 directly above the vapor deposition source openings 31, and the amount decreases progressively toward outward areas.

In normal vapor deposition, vapor deposition particles emitted from a single vapor deposition source opening have the above distribution. However, in a vapor deposition device used for mass production of a typical organic EL display device, a plurality of such single vapor deposition source openings are provided such that their distributions intentionally overlap. This results in a uniform distribution of film thickness on the target substrate.

However, with the vapor deposition device 1, as described above, vapor deposition particles 310 which travel toward a single one of the target regions 202 are limited, and vapor deposition source openings 31 which emit vapor deposition particles 310 travelling toward a single one of the target regions 202 are also limited.

As such, in a case where control of the vapor deposition rate etc. is not carried out, while problems such as indistinct outlines at edges of the mask openings 12 and failure to form part of a pixel will be remedied, there will be an increase in film thickness of the vapor-deposited films 300 particularly in a portion of each of the target regions 202 which portion corresponds to a central portion of a respective one of the limiting plate openings 23 in a planar view. This results in a non-uniform distribution of film thickness in each of the target regions 202.

In Embodiment 2, a uniform distribution of film thickness is achieved in each of the target regions 202 by causing a relative decrease in the vapor deposition rate of vapor deposition particles 310 emitted from those of the vapor deposition source openings 31 which are directly below limiting plate openings 23, as indicated by a dashed line R in FIG. 5.

<Method for Adjusting Vapor Deposition Rate Distribution>

A vapor deposition rate distribution is adjusted by (i) an arrangement of the limiting plates 22 with respect to the target regions 202, (ii) the shape of the limiting plates 22, and (iii) emission characteristics of each of the vapor deposition source openings 31.

A method for adjusting the vapor deposition rate distribution is not particularly limited. Methods which can be employed include: a method in which vapor deposition source openings 31 are provided directly under the limiting plate openings 23 at a period (i.e., at a nozzle density) which differs from that of vapor deposition source openings 31 in other regions; a method in which vapor deposition source openings 31 provided directly under the limiting plate openings 23 have a shape which differs from that of vapor deposition source openings 31 in other regions; and a method in which vapor deposition source 30 has temperatures which differ between regions directly under the limiting plate openings and other regions.

For example, FIG. 5 exemplarily illustrates a case where the vapor deposition source openings 31 are provided so as to be uniformly spaced. However, it is possible to decrease the vapor deposition rate in regions directly below limiting plate openings 23 relative to the vapor deposition rate in other areas by configuring the vapor deposition source 30 such that vapor deposition source openings 31 in a region opposite to one of the limiting plate openings 23 are provided at a density which is less than that of vapor deposition source openings 31 provided in other regions.

Note that the alteration of intervals between vapor deposition source openings in order to achieve uniform thickness of a vapor-deposited film in normal vapor deposition has been disclosed in, for example, Patent Literature 2.

Patent Literature 2 does not involve using the limiting plate unit 20, nor does it involve causing vapor deposition particles 310 emitted from a single vapor deposition source opening 31 to enter a plurality of target regions 202 which correspond to the single vapor deposition source opening 31. As such, the arrangement of holes formed in a vapor deposition source as disclosed in Patent Literature 2 cannot be applied as-is to the vapor deposition device 1 in accordance with Embodiment 2. However, with Embodiment 2, for example, in a case where the vapor deposition source openings 31 are configured to be provided at uniform intervals, a uniform thin film of the vapor-deposited films 300 can be achieved in each of the target regions 202 by altering the configuration so as to provide a relatively greater number of vapor deposition source openings 31 which will deposit vapor deposition particles 310 in portions of the target regions 202 where the vapor-deposited films 300 would otherwise be relatively thinly deposited.

Furthermore, it is possible to increase the vapor deposition rate by increasing the area of a vapor deposition source opening 31. As such, it is possible to relatively decrease the vapor deposition rate in regions directly below the limiting plate openings 23 as described above by decreasing an area of each of the vapor deposition source openings 31 which are directly below limiting plate openings 23, relative to an area of each of the vapor deposition source openings 31 in other regions (or, in other words, by relatively increasing the area of each of the vapor deposition source openings 31 in regions other than regions directly below the limiting plate openings 23).

Furthermore, a vapor deposition rate tends to increase as temperature increases. As such, the same effect as above can be achieved by employing a temperature distribution that follows the vapor deposition rate distribution indicated by the dashed line R in FIG. 5, so that a vapor deposition temperature of each of the vapor deposition source openings 31 which are opposite to limiting plate openings 23 is lower that a vapor deposition temperature of each of the vapor deposition source openings 31 which are opposite to the limiting plates 22.

In this way, with Embodiment 2 it is possible to achieve a uniform distribution of film thickness by controlling a vapor deposition rate in accordance with a vapor deposition material and the like so as to obtain a desired vapor deposition rate.

### Embodiment 3

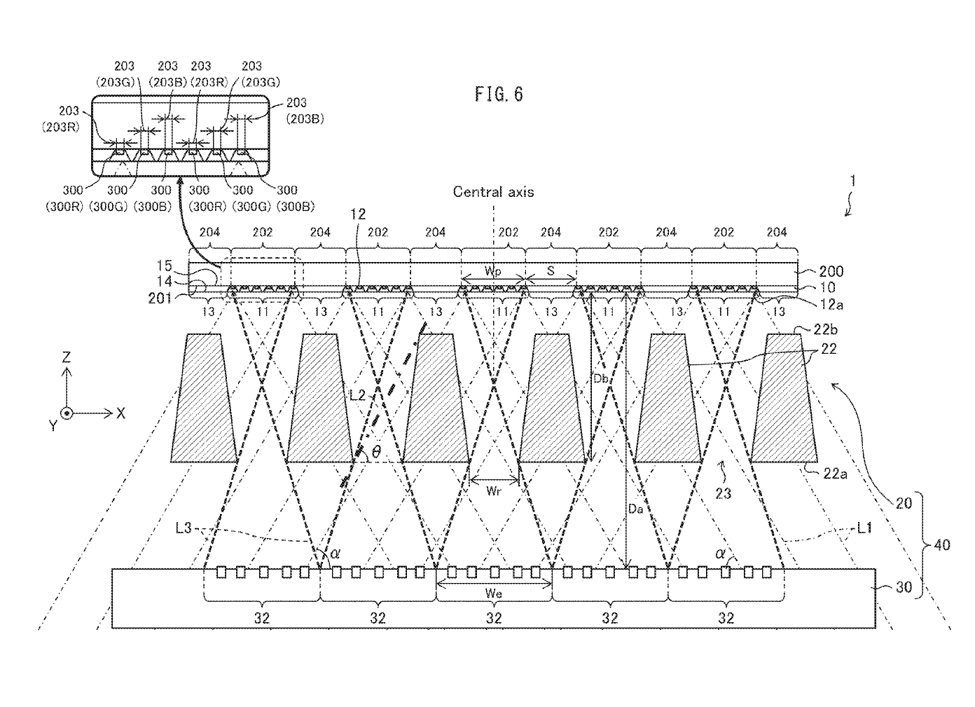

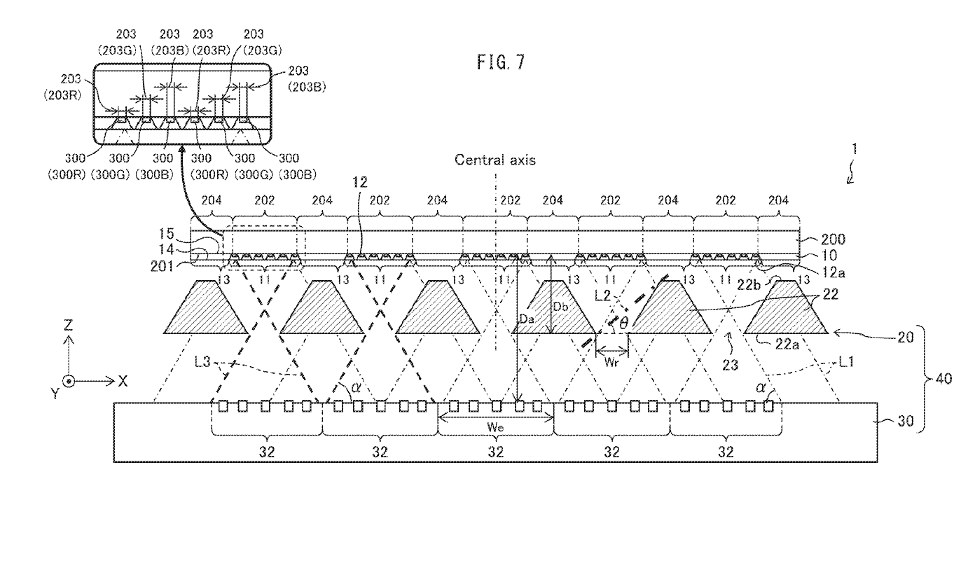

The following description will discuss another embodiment of the present invention, primarily with reference to FIGS. 6 and 7. The description below will deal mainly with how the present embodiment differs from Embodiments 1 and 2. Any member of the present embodiment that is identical in function to a corresponding member of Embodiment 1 or 2 is assigned a common reference numeral, and is not described here.

FIG. 6 is a cross-sectional view illustrating a basic configuration of a vapor deposition device 1 in accordance with Embodiment 3.

As described above, in Embodiments 1 and 2, vapor deposition particles 310 emitted from a single one of the vapor deposition source openings 31 enter a plurality of target regions 202.

As a point of difference from the vapor deposition device 1 of each of Embodiments 1 and 2 (see, for example, FIG. 1), a vapor deposition device 1 in accordance with Embodiment 3 is configured such that there is a one-to-one correspondence between each of the target regions 202 and a respective one of vapor deposition source opening formation regions (hereinafter, “source opening formation regions”) 32, each of the source opening formation regions 32 corresponding to a respective one of the target regions 202 as indicated by bold dashed lines L3 in FIG. 6.

A source opening formation region 32 corresponding to a respective one of the target regions 202 refers to a region in which it is possible to form vapor deposition source openings 31 which will emit vapor deposition particles 310 that will pass through the same mask opening region 11 and enter the respective one of the target regions 202.

In the vapor deposition device 1 in accordance with Embodiment 3, the limiting plates 22 are formed so as to have a height (length as measured in the Z axis direction) which is greater than in Embodiment 1 such that vapor deposition particles 310 which enter a specific one of the target regions 202 are limited to vapor deposition particles 310 from a specific, opposing one of the source opening formation regions 32.

As such, in Embodiment 3, a film thickness and distribution of film thickness of the vapor-deposited films 300 in each of the target regions 202 can be controlled independently from the other target regions 202. Embodiment 3 can therefore be expected to allow both improved controllability and improved mass production efficiency.

<Source Opening Formation Regions 32>

The following description will discuss design conditions for the source opening formation regions 32.

A width of each of the source opening formation regions 32 can be expressed by the following Formula (3);

We=Da/Db×Wr+(Da/Db−1)×Wp (3)

where: We is the width, as measured in the X axis direction, of each of the source opening formation regions 32; Wp is a width, as measured in the X axis direction, of each of the target regions 202; Wr is a width of each of the limiting plate openings 23 as measured at a face of each of the limiting plate openings 23 which face is on a side toward the surface 22a of the limiting plate unit 20, the surface 22a facing the vapor deposition source 30; Da is a distance from (a) the target surface 201 of the target substrate 200 to (b) a surface of the vapor deposition source 30 on which surface the vapor deposition source openings 31 are formed; and Db is a distance from (a) the target surface 201 of the target substrate 200 to (b) the surface 22a of each of the limiting plates 22 which surface 22a faces the vapor deposition source 30.

In a case where the width We of mutually adjacent ones of the source opening formation regions 32 is increased such that the mutually adjacent ones of the source opening formation regions 32 completely overlap, source opening formation regions 32 will not be independent, and vapor deposition particles 310 which can enter a specific one of the target regions 202 will not be limited to vapor deposition particles 310 from a specific, opposing one of the source opening formation regions 32.

Overlapping of mutually adjacent ones of the source opening formation regions 32 refers to overlapping of a first source opening formation region and a second source opening formation region, where (i) the first source opening formation region is one of the source opening formation regions 32 in which one it is possible to form vapor deposition source openings 31 which emit vapor deposition particles 310 that enter a first one of the target regions 202 and (ii) the second source opening formation region is one of the source opening formation regions 32 in which one it is possible to form vapor deposition source openings 31 which emit vapor deposition particles 310 that enter a second one of the target regions 202, the second one of the target regions being adjacent to the first one of the target regions 202.

Note that, as described above, each of the source opening formation regions 32 is a region of the vapor deposition source 30 in which it is possible to form vapor deposition source openings 31 which emit vapor deposition particles 310 that pass through the same one of the mask opening regions 11 and enter a respective one of the target regions 202. As such, the source opening formation regions 32 do not indicate which regions the vapor deposition source openings 31 are actually formed in. In other words, the source opening formation regions 32 are each a region in which, no matter where vapor deposition source openings 31 are formed within the region, the vapor deposition source openings 31 in the same source opening formation region 32 will emit vapor deposition particles 310 that pass through the same one of the mask opening regions 11 and enter one of the target regions 202 which one corresponds to the source opening formation region 32.

As such, even in a case where source opening formation regions 32 overlap, as long as vapor deposition source openings are not provided in overlapping portions of the source opening formation regions 32, it is possible for the target regions 202 and the source opening formation regions 32 to be in one-to-one correspondence. In other words, as long as each of the source opening formation regions 32 includes at least a portion which does not overlap with other source opening formation regions 32, it is possible to achieve one-to-one correspondence between the target regions 202 and the source opening formation regions 32 by providing the vapor deposition source openings 31 only in such portions of no overlap.

However, in a case where mutually adjacent ones of the source opening formation regions 32 overlap completely, there will be an absence of portions of no overlap.

Therefore, in order to prevent mutually adjacent ones of the source opening formation regions 32 from overlapping completely, We can be set so as to satisfy the following Formula (4):

We<2×(Wp+S) (4)

This makes it possible to limit vapor deposition particles 310 which enter a specific one of the target regions 202 to being vapor deposition particles 310 emitted from vapor deposition source openings 31 within a specific, opposing one of the source opening formation regions 32.

A region in which source opening formation regions 32 overlap is preferably small, as being small enables more efficient use of the length of the vapor deposition source 30 as measured in the X axis direction.

In other words, as described above, in a case where vapor deposition source openings 31 are provided in a region where mutually adjacent ones of the source opening formation regions 32 overlap, the target regions 202 and the source opening formation regions 32 will not be in one-to-one correspondence. As such, an absence of regions where mutually adjacent ones of the source opening formation regions 32 overlap allows for more efficient use of the length of the entire region of the vapor deposition source 30 in which vapor deposition source openings 31 can be provided.

As such, it is preferable to set We so as to satisfy the following Formula (5):

We<Wp+S (5).

In such a case, mutually adjacent ones of the source opening formation regions 32 will not overlap, and it is possible to, for example, provide mutually adjacent ones of the source opening formation regions 32 so as to be spaced from each other. In other words, as illustrated in FIG. 6, it is possible set (i) a distance between mutually adjacent vapor deposition source openings 31 which sandwich a boundary between mutually adjacent ones of the source opening formation regions 32 so as to be greater than (ii) a distance between mutually adjacent vapor deposition openings 31 within each of the source opening formation regions 32. This provides a space between groups of vapor deposition source openings 31, each group emitting vapor deposition particles 310 which enter a respective one of the target regions 202. Such a configuration makes it possible to form the source opening formation regions 32 so as to be completely independent from each other.

However, it is not preferable to set We to be excessively small, since doing so means that within We, a group of vapor deposition source openings 31 which emit vapor deposition particles 310 that enter the same one of the target regions 202 may (depending on a ratio of (i) the length of the vapor deposition source 30 as measured in the X axis direction to (ii) the width of each of the vapor deposition source openings 31 as measured in the X axis direction) be packed tightly, with little space between mutually adjacent ones of the vapor deposition source openings 31. It is therefore preferable to set We in accordance with (i) the length of the vapor deposition source 30 as measured in the X axis direction and (ii) the width of each of the vapor deposition source openings 31 as measured in the X axis direction, such that We falls within a range that is feasible from a design standpoint.

Other than the above-described point, the vapor deposition device 1 of Embodiment 3 is identical to the vapor deposition device 1 of Embodiment 1.

In FIG. 6, the limiting plates 22 are configured to have a height (length as measured in the Z axis direction) which is greater than in Embodiment 1, thereby increasing a space limited by the limiting plates 22 so as to prevent partial overlap (for example, as illustrated in FIG. 1) of (i) a group of vapor deposition source openings 31 which emit vapor deposition particles 310 that enter a specific one of the target regions 202 and (ii) another group of vapor deposition source openings 31 which emit vapor deposition particles 310 that enter one of the target regions 202 adjacent to the specific one of the target regions 202. However, Embodiment 3 is not limited to this.

Furthermore, in Embodiment 3 it is of course preferable to employ a rate distribution within each of the source opening formation regions 32, similarly to Embodiment 2, in order to achieve a uniform distribution of film thickness.

<Variations>

FIG. 7 is a cross-sectional view illustrating another configuration of the vapor deposition device 1 in accordance with Embodiment 3.

Note that in FIG. 7, the bold dashed lines L3 overlap with the dotted and dashed lines L1. As such, for convenience, the bold dashed lines L3 are shown only in some regions.

With Embodiment 3, the one-to-one correspondence between the target regions 202 and the source opening formation regions 32 can also be achieved by bringing the vapor deposition source 30 closer, as illustrated in FIG. 7.

In the vapor deposition device 1 in accordance with Embodiment 3, the limiting plates 22 are formed so as to have a height (length as measured in the Z axis direction) which is greater than in Embodiment 1 such that vapor deposition particles 310 which enter a specific one of the target regions 202 are limited to vapor deposition particles 310 from a specific, opposing one of the source opening formation regions 32.

Other methods for achieving the one-to-one correspondence between the target regions 202 and the source opening formation regions 32 include, for example, (i) decreasing the width Wr and (ii) increasing the distance Db with respect to the distance Da.

Decreasing the width Wr limits (i.e., decreases) a width of a region of the vapor deposition mask 10 which region is opposite a target region 202 with respect to a limiting plate opening 23. As such, the one-to-one correspondence between the target regions 202 and the source opening formation regions 32 can be achieved by, for example, decreasing the width Wr such that mutually adjacent ones of the source opening formation regions 32 are spaced from each other.

Increasing the distance Db with respect to the distance Da (in other words, decreasing Da/Db) is equivalent to increasing the height of the limiting plates 22.

Note that Da/Db is not particularly limited and is set or altered in accordance with, for example, the type of the vapor deposition material and the shape of the limiting plates 22. For example, Da/Db can be set qualitatively such that Da/Db<2.

Thus, as described above, Embodiment 3 can be altered in various ways in accordance with the descriptions above while still achieving the effects of Embodiment 3.

### Embodiment 4

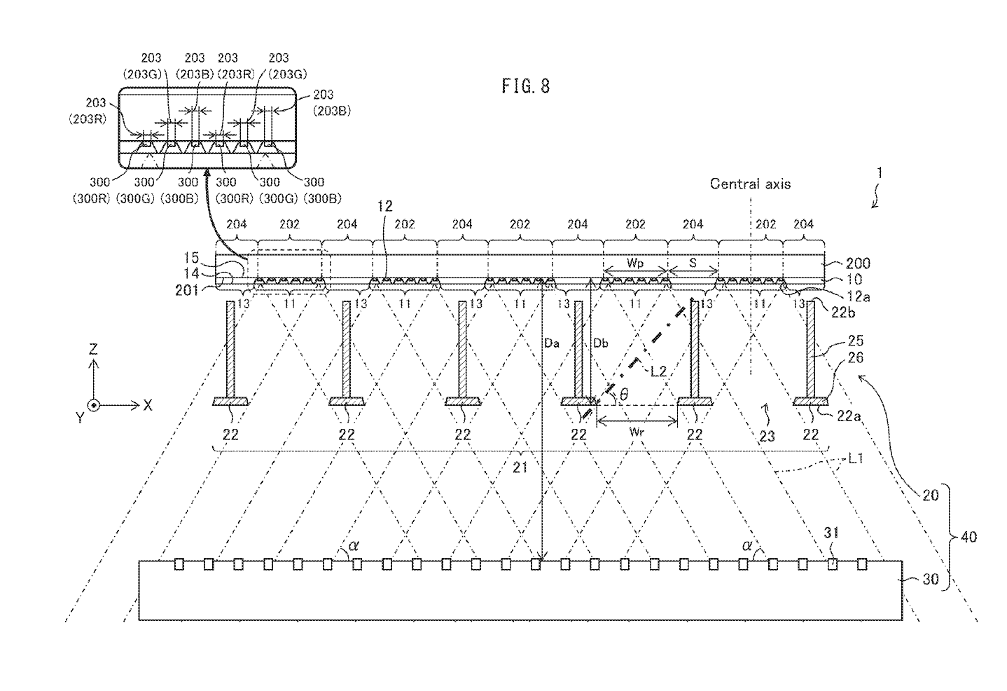

The following description will discuss yet another embodiment of the present invention, primarily with reference to FIG. 8. The description below will deal mainly with how the present embodiment differs from Embodiments 1, 2, and 3. Any member of the present embodiment that is identical in function to a corresponding member of Embodiments 1, 2, or 3 is assigned a common reference numeral, and is not described here.

FIG. 8 is a cross-sectional view illustrating a basic configuration of a vapor deposition device 1 in accordance with Embodiment 4.

In the vapor deposition device 1 in accordance with Embodiment 4, a limiting plate unit 20 has limiting plates 22 each having a T-shaped cross-section. Other than this point, the vapor deposition device 1 in accordance with Embodiment 4 is identical to the vapor deposition device 1 in accordance with each of Embodiments 1 to 3.

<Limiting Plates 22>

The limiting plates 22 in accordance with Embodiment 4 each include (i) a blocking wall section 25 constituted by a plate-like member whose main surface is in a YZ plane and (ii) a flange section 26 constituted by a plate-like member whose main surface is in an XY plane, the flange section 26 being provided at a lower end surface (that is, bottom surface) of the blocking wall section 25 so as to protrude in an eaves-like manner toward adjacent ones of the limiting plates 22.

Note that the design parameters of Embodiments 1 to 3 remain the same in Embodiment 4 so that the vapor deposition device 1 of Embodiment 4 is designed such that the above formulas are satisfied.

Embodiment 4 enables a reduction in the volume of the limiting plates 22. This makes it possible to increase the volume of space in which the vapor deposition particles 310 fly. As such, it is possible to prevent a problem where decreased space between the vapor deposition source 30 and the vapor deposition mask 10 causes a steep rise in pressure occurring between the vapor deposition source 30 and limiting plates 22 and in the limiting plate openings 23. Furthermore, by decreasing the volume of the limiting plates 22, Embodiment 4 also enables a reduction in the weight of the limiting plate unit 20. This can be advantageous in terms of device design by enabling, for example, a decrease in the load borne by the holding member which holds the limiting plate unit 20.

Furthermore, by configuring the limiting plates 22 to include the flange section 26, it becomes possible to catch, with the flange section 26, vapor deposition material which has come off the blocking wall section 25. This advantageously prevents the vapor deposition material which has come off from falling onto the vapor deposition source 30.

In FIG. 8, the blocking wall section 25 is planar so as to be substantially parallel to the Z axis. Note, however, that this is a non-limiting example, and the blocking wall section 25 may have any shape. For example, the blocking wall section 25 may be planar so as to be inclined with respect to the Z axis, or the blocking wall section 25 may alternatively have a curved shape. Furthermore, in FIG. 8, the blocking wall section 25 is a thin plate which has a substantially constant thickness, but this is a non-limiting example. For example, the blocking wall section 25 may have a wedge-like cross section so as to become thinner towards a tip thereof.

[Recap]

A vapor deposition device 1 in accordance with Aspect 1 of the present invention is a vapor deposition device for forming, on a target substrate 200 having at least one target region 202, a plurality of vapor-deposited films 300 having a predetermined pattern which are spaced from each other in at least a first direction (a direction along a side of the at least one target region 202; an X axis direction), the plurality of vapor-deposited films 300 being formed in the at least one target region 202, the vapor deposition device including: a vapor deposition source 30 having a plurality of vapor deposition source openings 31 for emitting vapor deposition particles 310; a vapor deposition mask 10 provided opposite to the at least one target region 202, the vapor deposition mask 10 having a mask opening region 11 constituted by a plurality of mask openings 12 provided along at least the first direction in correspondence with the predetermined pattern of the plurality of vapor-deposited films 300, each of the plurality of mask openings 12 having a cross-sectional shape which is tapered toward the target substrate; and a limiting plate unit 20 provided between the vapor deposition source 30 and the vapor deposition mask 10, the limiting plate unit 20 having a plurality of limiting plates 22 which are provided along at least the first direction so as to be spaced from each other, the limiting plate unit 20 being configured such that, in a cross section of the limiting plate unit 20 which cross section is parallel to the first direction, (i) the limiting plate unit 20 includes at least one limiting plate opening 23, each of which is formed between a respective pair of mutually adjacent ones of the plurality of limiting plates 22 and opposite to a respective one of the at least one target region 202 such that the at least one limiting plate opening 23 and the at least one target region 202 are in one-to-one correspondence, (ii) a central axis of each of the at least one limiting plate opening 23 is aligned with a central axis of a respective one of the at least one target region 202, and (iii) the following Formula (1) is satisfied:

Wr≤2/tanα×Db−Wp (1)

where Wp is a width, as measured in the first direction, of each of the at least one target region 202; Wr is a width of each of the at least one limiting plate opening 23 as measured in the first direction at a face of each of the at least one limiting plate opening which face is on a side toward a surface of the limiting plate unit 20 which surface faces the vapor deposition source 30; Db is a distance from (a) a target surface 201 of the target substrate 200 to (b) a surface 22a of each of the limiting plates 22 which surface 22a faces the vapor deposition source 30; and α is an angle of inclination of an opening wall 12a of each of the plurality of mask openings 12 as observed in a cross section of the vapor deposition mask 10 which cross section is parallel to the first direction.

In other words, a vapor deposition device 1 in accordance with Aspect 1 is a vapor deposition device for forming, on a target substrate 200 having at least one target region 202, a plurality of vapor-deposited films 300 having a predetermined pattern which are spaced from each other in at least a first direction, the plurality of vapor-deposited films 300 being formed in the at least one target region 202, the vapor deposition device including: a vapor deposition source 30 having a plurality of vapor deposition source openings 31 for emitting vapor deposition particles 310; a vapor deposition mask 10 provided opposite to the at least one target region 202, the vapor deposition mask 10 having a mask opening region 11 constituted by a plurality of mask openings 12 provided along at least the first direction in correspondence with the predetermined pattern of the plurality of vapor-deposited films 300, each of the plurality of mask openings 12 having a cross-sectional shape which is tapered toward the target substrate; and a limiting plate unit 20 provided between the vapor deposition source 30 and the vapor deposition mask 10, the limiting plate unit 20 having a plurality of limiting plates 22 which are provided along at least the first direction so as to be spaced from each other, the limiting plate unit 20 being configured such that in a cross section of the limiting plate unit 20 which cross section is parallel to the first direction, (i) the limiting plate unit 20 includes at least one limiting plate opening 23, each of which is formed between a respective pair of mutually adjacent ones of the plurality of limiting plates 22 and opposite to a respective one of the at least one target region 202 such that the at least one limiting plate opening 23 and the at least one target region 202 are in one-to-one correspondence, and (ii) the limiting plate unit 20 prevents entry into the plurality of mask openings 12 by vapor deposition particles 310 flying at an angle which is less than an angle of inclination (shadow critical angle α) of an opening wall 12a of each of the plurality of mask openings 12 as observed in a cross section of the vapor deposition mask 10 which cross section is parallel to the first direction.

With the vapor deposition device 1, entry into the at least one target region 202 is prevented for all vapor deposition particles 310 whose angle of entry into the at least one limiting plate opening 23 is less than an angle of inclination of an opening wall 12a of each of the plurality of mask openings 12 as observed in a cross section of the vapor deposition mask 10 which cross section is parallel to the first direction. As such, the limiting plate unit 20 limits vapor deposition particles 310 which reach the mask openings 12 to being only those vapor deposition particles 310 whose angle of entry is not less than an angle of inclination of an opening wall 12a of each of the plurality of mask openings 12 as observed in a cross section of the vapor deposition mask 10 which cross section is parallel to the first direction, which angle of inclination is a shadow critical angle. This makes it possible to achieve accurate vapor deposition patterning without a shadow.

In Aspect 2 of the present invention, the vapor deposition device 1 in accordance with Aspect 1 is preferably arranged such that the plurality of vapor deposition source openings 31 are formed such that two or more vapor deposition source openings from among the plurality of vapor deposition source openings 31 are opposite to each one of the at least one target region 202.

With the above configuration, it is possible to greatly increase a vapor deposition rate in comparison to a configuration where the vapor deposition source openings 31 and the at least one limiting plate opening 23 have a one-to-one relationship. This makes it possible to enhance mass production efficiency and makes it easy to design a vapor deposition source.

In Aspect 3 of the present invention, the vapor deposition device 1 in accordance with Aspect 1 or 2 is preferably arranged such that: the at least one target region 202 includes a plurality of target regions which are provided along at least the first direction and separated by a film-non-formation region 204 provided between each of the plurality of target regions; and the limiting plate unit 20 satisfies the following Formula (2):

(Db/tanθ)<(Wr+Wp)/2+S (2)

where S is a width, as measured in the first direction, of the film-non-formation region 204; and θ is an angle of inclination of a line (L2) which connects, in each of the at least one limiting plate opening 23, (i) a lower end of a first limiting plate 22 of a mutually opposed pair of the plurality of limiting plates 22 and (ii) an upper end of a second limiting plate 22 of the mutually opposed pair of the plurality of limiting plates 22, the mutually opposed pair of the plurality of limiting plates 22 being opposed in the first direction.

With the above configuration, in a case where a lower end of one of the limiting plates 22 is used as a reference position, the following holds true in a planar view: a distance from (i) the reference position to (ii) a position of a vapor deposition particle which reaches a position closest to the adjacent target region 202 of the target substrate 200 is shorter than a distance from (iii) the reference position to (iv) a position at an end of the adjacent target region 202.

The above configuration therefore makes it possible to prevent vapor deposition particles 310 which have been emitted from vapor deposition source openings 31 corresponding to (i) a respective one of the at least one target region 202 and (ii) a respective one of the at least one limiting plate opening 23 from passing through the respective one of the at least one limiting plate opening 23 and entering an adjacent target region 202 which is adjacent to the respective one of the at least one target region 202.

In Aspect 4 of the present invention, the vapor deposition device 1 in accordance with any one of Aspects 1 to 3 is preferably arranged such that: the at least one target region 202 includes a plurality of target regions which are provided along at least the first direction; and the following Formula (4) is satisfied:

We<2×(Wp+S) (4)

where We is a width, as measured in the first direction, of each of a plurality of formation regions (source opening formation regions 32) of the vapor deposition source 30, the plurality of formation regions each being for formation of the plurality of vapor deposition source openings 31, the plurality of formation regions each corresponding to a respective one of the plurality of target regions 202.

With the above configuration, mutually adjacent ones of the source opening formation regions 32 are prevented from overlapping completely. As long as each of the source opening formation regions 32 includes, as in the above configuration, at least a portion which does not overlap with other source opening formation regions 32, it is possible to achieve one-to-one correspondence between the target regions 202 and the source opening formation regions 32 by providing the vapor deposition source openings 31 only in such portions of no overlap. As such, the above configuration makes it possible to limit vapor deposition particles 310 which enter a specific one of the target regions 202 to being vapor deposition particles 310 emitted from vapor deposition source openings 31 within a specific, opposing one of the source opening formation regions 32.

In Aspect 5 of the present invention, the vapor deposition device 1 in accordance with Aspect 4 is preferably arranged such that the following Formula (5) is satisfied:

We<Wp+S (5).

With the above configuration, mutually adjacent ones of the source opening formation regions 32 will not overlap, and it is possible to form the source opening formation regions 32 so as to be completely independent from each other.

In Aspect 6 of the present invention, the vapor deposition device 1 in accordance with any one of Aspects 1 to 5 is preferably arranged such that a vapor deposition rate of vapor deposition particles 310 emitted by the vapor deposition source from ones of the plurality of vapor deposition source openings 31 which ones are provided in a region opposite to the at least one limiting plate opening 23 is lower than a vapor deposition rate of vapor deposition particles 310 emitted by the vapor deposition source 30 from ones of the plurality of vapor deposition source openings 31 which ones are provided in a region other than the region opposite to the at least one limiting plate opening 23.

The above configuration makes it possible to achieve a uniform distribution of film thickness of the vapor-deposited films 300 in each of the at least one target region 202.

In Aspect 7 of the present invention, the vapor deposition device 1 in accordance with any one of Aspects 1 to 6 is preferably arranged such that each of the plurality of limiting plates 22 has a cross-sectional shape which is tapered toward the target substrate.

In a case where each of the limiting plates 22 has a cross-sectional shape which is tapered toward the vapor deposition source, the limiting plate unit 20 will not satisfy the above Formulas (1) and (2). However, in a case where each of the limiting plates 22 has a cross-sectional shape which is tapered toward the target substrate, it is possible to form the limiting plate unit 20 in a manner so as to satisfy the above Formulas (1) and (2).

In Aspect 8 of the present invention, the vapor deposition device 1 in accordance with any one of Aspects 1 to 6 is preferably arranged such that each of the plurality of limiting plates 22 has a T-shaped cross section and includes: a blocking wall section 25 constituted by a plate-like member; and a flange section 26 constituted by a plate-like member provided at a bottom surface of the blocking wall section 25 so as to protrude in an eaves-like manner toward adjacent ones of the plurality of limiting plates 22.

The above configuration enables a reduction in the volume of the plurality of the limiting plates 22. This makes it possible to increase the volume of space in which the vapor deposition particles 310 fly. As such, the above configuration makes possible to prevent a steep rise in pressure from occurring (i) between the vapor deposition source 30 and the plurality of limiting plates 22 and (ii) in the at least one limiting plate opening 23. The above configuration also makes it possible to reduce the weight of the limiting plate unit 20. Furthermore, with the above configuration, each of the plurality of limiting plates 22 includes a flange section 26. This makes it possible to prevent vapor deposition material which has come off from the blocking wall section 25 from falling onto the vapor deposition source 30.

In Aspect 9 of the present invention, the vapor deposition device 1 in accordance with any one of Aspects 1 to 8 is preferably arranged such that: the at least one target region 202 includes a plurality of target regions 202 which are (i) provided along the first direction (X axis direction) and a second direction (Y axis direction) orthogonal to the first direction and (ii) separated by a film-non-formation region 204 provided between each of the plurality of target regions 202; the vapor deposition mask 10 has a size so as to be large enough to cover the plurality of target regions 202 of the target substrate 200; the vapor deposition mask 10 and the target substrate 200 are positionally fixed with respect to each other; the limiting plate unit 20 and the vapor deposition source 30 are positionally fixed with respect to each other; each of the plurality of limiting plates 22 has a width, as measured in the second direction, which is less than that of the target substrate 200 and less than that of the vapor deposition mask 10; the vapor deposition device 1 further includes a moving device (at least one of the substrate moving device 5 and the vapor deposition unit moving device 6) configured to move (i) one of (a) a combination of the target substrate 200 and the vapor deposition mask 10 and (b) a combination of the limiting plate unit 20 and the vapor deposition source 30 with respect to the other or (ii) both (a) the combination of the target substrate 200 and the vapor deposition mask 10 and (b) the combination of the limiting plate unit 20 and the vapor deposition source 30 with respect to each other, such that a scanning direction is the second direction; and the vapor deposition device 1, while carrying out scanning in the scanning direction, causes the vapor deposition particles 310 emitted by the vapor deposition source 30 to be vapor-deposited onto the target substrate 200 through the limiting plate unit 20 and the vapor deposition mask 10.

The above configuration makes it possible, even for the target substrate 200 having a large surface area, to achieve high-precision patterning without a shadow occurring. This configuration also makes it possible to achieve high-definition patterning over a large surface area even when using the vapor deposition source 30 and the limiting plate unit 20 which are both relatively small. As such, the configuration enables enhanced mass production efficiency.

A method of vapor deposition in accordance with Aspect of the present invention includes forming, on a target substrate 200 having at least one target region 202, a plurality of vapor-deposited films 300 having a predetermined pattern which are spaced from each other in at least a first direction, the plurality of vapor-deposited films 300 being formed in the at least one target region 202, the forming being carried out with use of a vapor deposition device 1 in accordance with any one of Aspects 1 to 9.

The above method brings about effects similar to those of Aspect 1.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### INDUSTRIAL APPLICABILITY

A vapor deposition device and a vapor deposition method in accordance with an embodiment of the present invention can each be suitably applied to, for example, production of various devices which production utilizes vapor deposition, an example being production of EL display devices such as organic EL display devices or inorganic EL display devices.

### Reference Signs List

1 Vapor deposition device

2 Film formation chamber

3 Mask holder

3a Mask mount

4 Magnet plate

5 Substrate moving device (moving device)

6 Vapor deposition unit moving device (moving device)

10 Vapor deposition mask

11 Mask opening region

12 Mask opening

12a Opening wall

13 Non-opening region

14 Surface (surface of vapor deposition mask which faces limiting plate unit)

15 Surface (surface of vapor deposition mask which faces target substrate)

20 Limiting plate unit

21 Limiting plate row

22 Limiting plate

22a Surface (surface of limiting plate unit which faces vapor deposition source)

22b Surface (surface of limiting plate unit which faces vapor deposition mask)

23 Limiting plate opening

24 Holding sections

25 Blocking wall section

26 Flange section

28 Cooling mechanism

30 Vapor deposition source

31, 31A Vapor deposition source opening

32 Source opening formation regions

40 Vapor deposition unit

41 Holder

200 Target substrate

201 Target surface

202 Target region

203, 203R, 203G, 203B Target pattern region

204 Film-non-formation region

300, 300R, 300G, 300B Vapor-deposited film

310, 311, 312, 314 Vapor deposition particles

α Shadow critical angle

β, β1, β2, β3 Angle of entry

1. A vapor deposition device for forming, on a target substrate having at least one target region, a plurality of vapor-deposited films having a predetermined pattern which are spaced from each other in at least a first direction, the plurality of vapor-deposited films being formed in the at least one target region, the vapor deposition device comprising:
a vapor deposition source having a plurality of vapor deposition source openings for emitting vapor deposition particles;
a vapor deposition mask provided opposite to the at least one target region, the vapor deposition mask having a mask opening region constituted by a plurality of mask openings provided along at least the first direction in correspondence with the predetermined pattern of the plurality of vapor-deposited films, each of the plurality of mask openings having a cross-sectional shape which is tapered toward the target substrate; and
a limiting plate unit provided between the vapor deposition source and the vapor deposition mask, the limiting plate unit having a plurality of limiting plates which are provided along at least the first direction so as to be spaced from each other, the limiting plate unit being configured such that, in a cross section of the limiting plate unit which cross section is parallel to the first direction, (i) the limiting plate unit includes at least one limiting plate opening, each of which is formed between a respective pair of mutually adjacent ones of the plurality of limiting plates and opposite to a respective one of the at least one target region such that the at least one limiting plate opening and the at least one target region are in one-to-one correspondence, (ii) a central axis of each of the at least one limiting plate opening is aligned with a central axis of a respective one of the at least one target region, and (iii) the following Formula (1) is satisfied:
Wr≤2/tanα×Db−Wp (1)
where Wp is a width, as measured in the first direction, of each of the at least one target region; Wr is a width of each of the at least one limiting plate opening as measured in the first direction at a face of each of the at least one limiting plate opening which face is on a side toward a surface of the limiting plate unit which surface faces the vapor deposition source; Db is a distance from (a) a target surface of the target substrate to (b) a surface of each of the limiting plates which surface faces the vapor deposition source; and a is an angle of inclination of an opening wall of each of the plurality of mask openings as observed in a cross section of the vapor deposition mask which cross section is parallel to the first direction.

2. The vapor deposition device according to claim 1, wherein the plurality of vapor deposition source openings are formed such that two or more vapor deposition source openings from among the plurality of vapor deposition source openings are opposite to each one of the at least one target region.

3. The vapor deposition device according to claim 1, wherein:
the at least one target region includes a plurality of target regions which are provided along at least the first direction and separated by a film-non-formation region provided between each of the plurality of target regions; and
the limiting plate unit satisfies the following Formula (2):
(Db/tanθ)<(Wr+Wp)/2+S (2)
where S is a width, as measured in the first direction, of the film-non-formation region; and θ is an angle of inclination of a line which connects, in each of the at least one limiting plate opening (i) a lower end of a first limiting plate of a mutually opposed pair of the plurality of limiting plates and (ii) an upper end of a second limiting plate of the mutually opposed pair of the plurality of limiting plates, the mutually opposed pair of the plurality of limiting plates being opposed in the first direction.

4. The vapor deposition device according to claim 1, wherein:
the at least one target region includes a plurality of target regions which are provided along at least the first direction; and
the following Formula (4) is satisfied:
We<2×(Wp+S) (4)
where We is a width, as measured in the first direction, of each of a plurality of formation regions of the vapor deposition source, the plurality of formation regions each being for formation of the plurality of vapor deposition source openings, the plurality of formation regions each corresponding to a respective one of the plurality of target regions.

5. The vapor deposition device according to claim 4, wherein the following Formula (5) is satisfied:
We<Wp+S (5).

6. The vapor deposition device according to claim 1, wherein a vapor deposition rate of vapor deposition particles emitted by the vapor deposition source from ones of the plurality of vapor deposition source openings which ones are provided in a region opposite to the at least one limiting plate opening is lower than a vapor deposition rate of vapor deposition particles emitted by the vapor deposition source from ones of the plurality of vapor deposition source openings which ones are provided in a region other than the region opposite to the at least one limiting plate opening.

7. The vapor deposition device according to claim 1, wherein each of the plurality of limiting plates has a cross-sectional shape which is tapered toward the target substrate.

8. The vapor deposition device according to claim 1, wherein each of the plurality of limiting plates has a T-shaped cross section and includes:
a blocking wall section constituted by a plate-like member; and
a flange section constituted by a plate-like member provided at a bottom surface of the blocking wall section so as to protrude in an eaves-like manner toward adjacent ones of the plurality of limiting plates.

9. The vapor deposition device according to claim 1, wherein:
the at least one target region includes a plurality of target regions which are (i) provided along the first direction and a second direction orthogonal to the first direction and (ii) separated by a film-non-formation region provided between each of the plurality of target regions;
the vapor deposition mask has a size so as to be large enough to cover the plurality of target regions of the target substrate;
the vapor deposition mask and the target substrate are positionally fixed with respect to each other;
the limiting plate unit and the vapor deposition source are positionally fixed with respect to each other;
each of the plurality of limiting plates has a width, as measured in the second direction, which is less than that of the target substrate and less than that of the vapor deposition mask;
the vapor deposition device further comprises a moving device configured to move (i) one of (a) a combination of the target substrate and the vapor deposition mask and (b) a combination of the limiting plate unit and the vapor deposition source with respect to the other or (ii) both (a) the combination of the target substrate and the vapor deposition mask and (b) the combination of the limiting plate unit and the vapor deposition source with respect to each other, such that a scanning direction is the second direction; and
the vapor deposition device, while carrying out scanning in the scanning direction, causes the vapor deposition particles emitted by the vapor deposition source to be vapor-deposited onto the target substrate through the limiting plate unit and the vapor deposition mask.

10. A method for vapor deposition comprising:
forming, on a target substrate having at least one target region, a plurality of vapor-deposited films having a predetermined pattern which are spaced from each other in at least a first direction, the plurality of vapor-deposited films being formed in the at least one target region, the forming being carried out with use of a vapor deposition device as recited in claim 1.
